(19) United States
(12) Patent Application Publication
(10) Pub. No.: US 2025/0344572 A1
(43) Pub. Date: Nov. 6, 2025

(54) DISPLAY DEVICE AND ELECTRONIC DEIVCE

(71) Applicant: Samsung Display Co., LTD., Yongin-si (KR)

(72) Inventors: SUNGJIN HONG, Yongin-si (KR); SUNHO KIM, Yongin-si (KR); Hyewon Kim, Yongin-si (KR); PILSUK LEE, Yongin-si (KR); CHUNG SOCK CHOI, Yongin-si (KR)

(73) Assignee: Samsung Display Co., LTD., Yongin-si (KR)

(21) Appl. No.: 19/016,263

(22) Filed: Jan. 10, 2025

(30) Foreign Application Priority Data
May 3, 2024 (KR) 10-2024-0059048

(51) Int. Cl. H10K 59/121; H10K 59/123

(52) U.S. Cl. CPC H10K 59/1213; H10K 59/123

(57) ABSTRACT

A display device includes a first light emitting element that emits first light and includes a plurality of sub-elements spaced apart from each other, a second light emitting element that emits second light, a third light emitting element that emits third light, a first pixel driving circuit electrically connected to the first light emitting element, a second pixel driving circuit electrically connected to the second light emitting element, and a third pixel driving circuit electrically connected to the third light emitting element. The first pixel driving circuit is disposed between the second pixel driving circuit and the third pixel driving circuit in a plan view.

### CROSS-REFERENCE TO RELATED APPLICATION(S)

This application claims priority to and benefits of Korean Patent Application No. 10-2024-0059048 under 35 U.S.C. § 119, filed on May 3, 2024, in the Korean Intellectual Property Office, the entire contents of which are incorporated herein by reference.

### BACKGROUND

### 1. Technical Field

Embodiments relate to a display device that provides visual information.

### 2. Description of the Related Art

The importance of display devices as communication medium, has been emphasized because of the increasing developments of information technology. A display device includes a light emitting element and a pixel driving circuit that drives the light emitting element. The light emitting element is driven by the pixel driving circuit and emits light. To enhance the reliability of the display devices, studies are being conducted to investigate the relationship between the light emitting element and the pixel driving circuit.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a display device with improved display quality.

Embodiments provide an electronic device including the display device.

However, embodiments of the disclosure are not limited to those set forth herein. The above and other embodiments will become more apparent to one of ordinary skill in the art to which the disclosure pertains by referencing the detailed description of the disclosure given below.

A display device according to an embodiment of the disclosure includes a first light emitting element that emits first light and includes a plurality of sub-elements spaced apart from each other, a second light emitting element that emits second light, a third light emitting element that emits third light, a first pixel driving circuit electrically connected to the first light emitting element, a second pixel driving circuit electrically connected to the second light emitting element, and a third pixel driving circuit electrically connected to the third light emitting element. The first pixel driving circuit may be disposed between the second pixel driving circuit and the third pixel driving circuit in a plan view.

In an embodiment, the plurality of sub-elements may include a first sub-element and a second sub-element, the first sub-element may overlap the second pixel driving circuit in a plan view, and the second sub-element may overlap the third pixel driving circuit in a plan view.

In an embodiment, the second light emitting element may overlap the second pixel driving circuit in a plan view, and the third light emitting element may overlap the third pixel driving circuit in a plan view.

In an embodiment, the first pixel driving circuit may be adjacent to the second pixel driving circuit in a first direction, and the third pixel driving circuit may be adjacent to the first pixel driving circuit in the first direction.

In an embodiment, the plurality of sub-elements may include a first sub-element and a second sub-element, the second sub-element may be spaced apart from the first sub-element in a direction between the first direction and a second direction intersecting the first direction, the second light emitting element may be spaced apart from the first sub-element in the second direction, and the third light emitting element may be spaced apart from the first sub-element in the first direction.

In an embodiment, the display device may further include a first connection electrode electrically connected to the first pixel driving circuit and overlapping the first pixel driving circuit in a plan view, a second connection electrode electrically connected to the second pixel driving circuit and overlapping the second pixel driving circuit in a plan view, and a third connection electrode electrically connected to the third pixel driving circuit and overlapping the third pixel driving circuit in a plan view.

In an embodiment, the display device may further include a first connection pattern electrically connected to the first connection electrode and surrounding at least a portion of the first light emitting element in a plan view, a second connection pattern electrically connected to the second connection electrode and surrounding at least a portion of the second light emitting element in a plan view, and a third connection pattern electrically connected to the third connection electrode and surrounding at least a portion of the third light emitting element in a plan view.

In an embodiment, the plurality of sub-elements may include a first sub-element and a second sub-element, the first connection pattern may include a first sub-pattern surrounding at least a portion of the first sub-element in a plan view, a second sub-pattern surrounding at least a portion of the second sub-element in a plan view, and a third sub-pattern electrically connecting the first sub-pattern and the second sub-pattern.

In an embodiment, the first sub-element may include a first sub-electrode electrically connected to the first sub-pattern, the second sub-element may include a second sub-electrode electrically connected to the second sub-pattern, the second light emitting element may include a first electrode electrically connected to the second connection pattern, and the third light emitting element may include a second electrode electrically connected to the third connection pattern.

In an embodiment, the display device may further include a separator disposed on the first connection pattern, the second connection pattern, and the third connection pattern, and separating the first sub-electrode, the second sub-electrode, the first electrode, and the second electrode from each other.

A display device according to an embodiment of the disclosure includes a circuit area including a first pixel driving circuit, a second pixel driving circuit adjacent to the first pixel driving circuit in a first direction, and a third pixel driving circuit adjacent to the second pixel driving circuit in the first direction, and a light emitting area partially overlapping the circuit area in a plan view and including a first light emitting area in which a first light emitting element that emits first light, electrically connected to the first pixel driving circuit, and includes a plurality of sub-elements spaced apart from each other is disposed, a second light emitting area in which a second light emitting element that emits second light and electrically connected to the second pixel driving circuit is disposed, and a third light emitting area in which a third light emitting element that emits third light and electrically connected to the third pixel driving circuit is disposed.

In an embodiment, the plurality of sub-elements may include a first sub-element and a second sub-element, and the first sub-element may overlap the second pixel driving circuit in a plan view.

In an embodiment, the second light emitting element may overlap the second pixel driving circuit in a plan view, and the third light emitting element may overlap the third pixel driving circuit in a plan view.

In an embodiment, the light emitting area may be defined as a rectangular planar shape having chamfered corners facing in a direction between the first direction and a second direction intersecting the first direction.

In an embodiment, the plurality of sub-elements may include a first sub-element and a second sub-element, the second sub-element may be spaced apart from the first sub-element in a direction between a direction opposite to the first direction and the second direction, the second light emitting element may be spaced apart from the first sub-element in the second direction, and the third light emitting element may be spaced apart from the first sub-element in the first direction.

In an embodiment, the display device may further include a first connection electrode electrically connected to the first pixel driving circuit and overlapping the first pixel driving circuit in a plan view, a second connection electrode electrically connected to the second pixel driving circuit and overlapping the second pixel driving circuit in a plan view, and a third connection electrode electrically connected to the third pixel driving circuit and overlapping the third pixel driving circuit in a plan view.

In an embodiment, the display device may further include a first connection pattern electrically connected to the first connection electrode and surrounding at least a portion of the first light emitting element in a plan view, a second connection pattern electrically connected to the second connection electrode and surrounding at least a portion of the second light emitting element in a plan view, and a third connection pattern electrically connected to the third connection electrode and surrounding at least a portion of the third light emitting element in a plan view.

In an embodiment, the plurality of sub-elements may include a first sub-element and a second sub-element, and the first connection pattern may include a first sub-pattern surrounding at least a portion of the first sub-element in a plan view, a second sub-pattern surrounding at least a portion of the second sub-element in a plan view, and a third sub-pattern electrically connecting the first sub-pattern and the second sub-pattern.

In an embodiment, the first sub-element may include a first sub-electrode electrically connected to the first sub-pattern, the second sub-element may include a second sub-electrode electrically connected to the second sub-pattern, the second light emitting element may include a first electrode electrically connected to the second connection pattern, and the third light emitting element may include a second electrode electrically connected to the third connection pattern.

In an embodiment, the display device may further include a separator disposed on the first connection pattern, the second connection pattern, and the third connection pattern, and separating the first sub-electrode, the second sub-electrode, the first electrode, and the second electrode from each other.

An electronic device according to an embodiment of the disclosure includes a display device and a power supply that provides power to the display device. The display device includes a first light emitting element that emits first light and includes a plurality of sub-elements spaced apart from each other, a second light emitting element that emits second light, a third light emitting element that emits third light, a first pixel driving circuit electrically connected to the first light emitting element, a second pixel driving circuit electrically connected to the second light emitting element, and a third pixel driving circuit electrically connected to the third light emitting element. The first pixel driving circuit may be disposed between the second pixel driving circuit and the third pixel driving circuit in a plan view.

In a display device according to embodiments of the disclosure, the display device may include connection electrodes electrically connecting cathodes of light emitting elements and pixel driving circuits, respectively. Since a pixel driving circuit electrically connected to a light emitting element including sub-elements is disposed between pixel driving circuits respectively connected to other light emitting elements in a plan view, a length (or an area) of the connection electrodes may be reduced. Since a shape of a unit light emitting area partially overlaps a circuit area (e.g., a unit circuit area) in a plan view, a length (or an area) of the connection electrodes may be reduced. Accordingly, parasitic capacitance by the connection electrodes may be reduced, and display quality of the display device may be improved.

### BRIEF DESCRIPTION OF THE DRAWINGS

An additional appreciation according to the embodiments of the disclosure will become more apparent by describing in detail the elements thereof with reference to the accompanying drawings, wherein:

FIG. 1A is a schematic plan view illustrating a display device according to an embodiment of the disclosure;

FIG. 1B is a schematic plan view illustrating a display device according to an embodiment of the disclosure;

FIG. 2A is a schematic diagram of an equivalent circuit illustrating an example of a circuit structure of a pixel included in the display device of FIGS. 1A and 1B;

FIG. 2B is a schematic diagram of an equivalent circuit illustrating an example of a circuit structure of a pixel included in the display device of FIGS. 1A and 1B;

FIG. 3 is a schematic plan view schematically illustrating a portion of the display device of FIGS. 1A and 1B;

FIG. 4 is a schematic enlarged view illustrating a portion of FIG. 3;

FIG. 5 is a schematic cross-sectional view taken along line I-I′ of FIG. 4;

FIG. 6 is a schematic cross-sectional view taken along line II-II′ of FIG. 4;

FIG. 7 is a schematic plan view illustrating a display device according to an embodiment of the disclosure;

FIG. 8 is a schematic enlarged view illustrating a portion of FIG. 7;

FIG. 9 is a schematic plan view illustrating a display device according to an embodiment of the disclosure;

FIG. 10 is a schematic enlarged view illustrating a portion of FIG. 9;

FIG. 11 is a schematic plan view illustrating a display device according to an embodiment of the disclosure;

FIG. 12 is a schematic enlarged view illustrating a portion of FIG. 11;

FIG. 13 is a schematic block diagram illustrating an electronic device according to an embodiment of the disclosure; and

FIG. 14 is a schematic view illustrating an example in which the electronic device of FIG. 13 is implemented as a smart phone.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Spatially relative terms, such as “beneath,” “below,” “under, “lower,” “above,” “upper,” “over,” “higher,” “side” (e.g., as in “sidewall”), and the like may be used herein for descriptive purposes, and thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the device in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

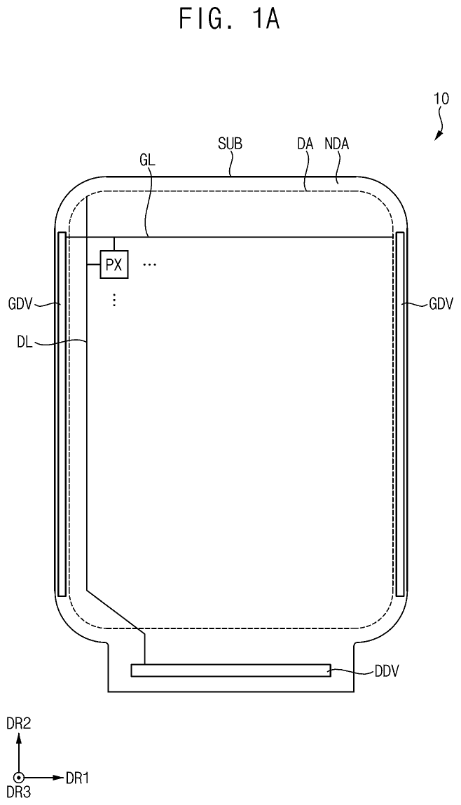

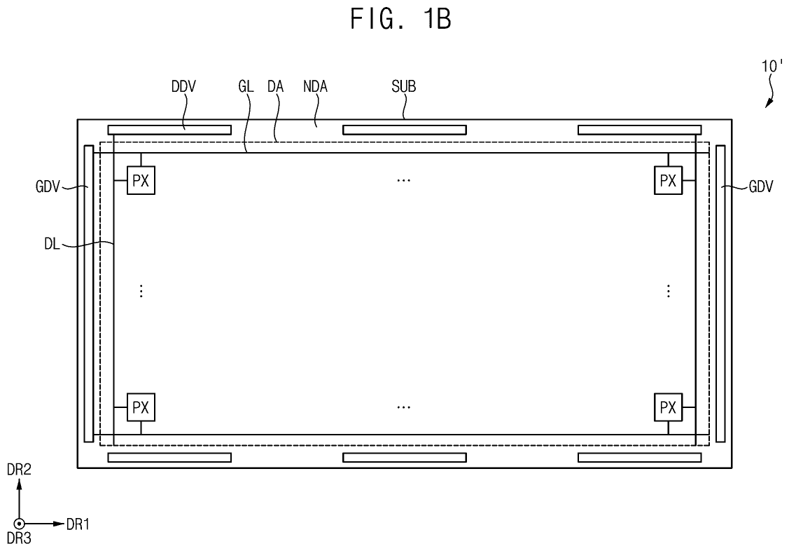

FIG. 1A is a schematic plan view illustrating a display device according to an embodiment of the disclosure. FIG. 1B is a schematic plan view illustrating a display device according to an embodiment of the disclosure.

Referring to FIGS. 1A and 1B, a display device 10 (or 10′) may be a device activated by an electrical signal. For example, the display device 10 may be used in a small-sized electronic device such as a smartphone, a mobile phone, a smart watch, a game console, a camera, or the like. The display device 10′ may be used in a medium to large-sized electronic device such as a laptop, a tablet PC, a television, a computer monitor, a vehicle monitor, an external billboard, or the like. FIG. 1A illustrates the display device 10 as an example of the small-sized display device, and FIG. 1B illustrates the display device 10′ as an example of the medium to large-sized display device.

The display device 10 (or 10′) may include a display area DA and a peripheral area NDA. The display area DA may be an area that generates light or controls a transmittance of light provided from an external light source to display an image. The peripheral area NDA may be disposed adjacent to (or be located around) the display area DA. For example, the peripheral area NDA may surround at least a portion of the display area DA in a plan view. In an embodiment, the peripheral area NDA may be an area that does not display an image. However, embodiments are not limited thereto, and an image may be displayed in at least a portion of the peripheral area NDA. For example, a light emitting element that emits light may be disposed in at least a portion of the peripheral area NDA.

The display device 10 (or 10′) may include a substrate SUB, pixels PX, a gate line GL, a data line DL, a data driver DDV, and a gate driver GDV.

The substrate SUB may be (or serve as) a base of the display device 10 (or 10′). In an embodiment, examples of materials that may be used as the substrate SUB may include glass, quartz, silicon, polymer, or the like. These may be used alone or in combination with each other. The substrate SUB may have a single-layer structure or a multi-layer structure in which layers including different materials are stacked each other.

The pixels PX may be disposed in the display area DA on the substrate SUB. The pixels PX may be electrically connected to the gate line GL and the data line DL. For example, the pixels PX may be disposed in a matrix form along a first direction DR1 and a second direction DR2 intersecting the first direction DR1. Each of the pixels PX may include a pixel driving circuit and a light emitting element. The light emitting element may emit light, and accordingly, an image may be displayed, for example, in a third direction DR3. For example, the third direction DR3 may be normal to a plane defined by the first and second directions DR1 and DR2.

The gate line GL and the data line DL may intersect with each other. The display device 10 (or 10′) may include gate lines GL and data lines DL. For example, each of the gate lines GL may generally extend in the first direction DR1, and the gate lines GL may be disposed (e.g., arranged) along the second direction DR2. Each of the data lines DL may generally extend in the second direction DR2, and the data lines DL may be arranged along the first direction DR1. However, embodiments are not limited thereto.

The data driver DDV may be disposed in the peripheral area NDA on the substrate SUB. The data driver DDV may generate a data voltage. The data driver DDV may output the data voltage to the data line DL. The data voltage may be applied to the pixels PX through the data line DL.

In an embodiment, the data driver DDV may be mounted on the substrate SUB. However, embodiments are not limited thereto, and the data driver DDV may be disposed on a flexible film coupled (e.g., fixed) to the substrate SUB. For example, the display device 10 (or 10′) may have a chip-on-film (COF) structure.

In an embodiment, the display device 10′ of FIG. 1B may include data drivers DDV. For example, the data drivers DDV may be disposed on sides (e.g., both sides) of the display area DA in the second direction DR2. For example, the data drivers DDV may be disposed along a long side of the display device 10′. However, embodiments are not limited thereto.

The gate driver GDV may be disposed in the peripheral area NDA on the substrate SUB. The gate driver GDV may generate a gate signal. The gate driver GDV may output the gate signal to the gate line GL. The gate signal may be applied to the pixels PX through the gate line GL. In an embodiment, the gate driver GDV may be disposed on sides (e.g., both sides) of the display area DA in the first direction DR1. However, embodiments are not limited thereto.

In an embodiment, a light emitting driver that generates a light emitting control signal may be further disposed in the peripheral area NDA. The light emitting control signal may be applied to the pixels PX through a light emitting control line.

The number or arrangement relationship of the data drivers DDV and the number or arrangement relationship of the gate drivers GDV illustrated in FIGS. 1A and 1B are merely examples, and embodiments are not limited thereto.

Although FIG. 1A illustrates the display device 10 of a substantially rectangular planar shape having a short side extending in the first direction DR1 and a long side extending in the second direction DR2, embodiments are not limited thereto. Although FIG. 1B illustrates the display device 10′ of a rectangular planar shape having a long side extending in the first direction DR1 and a short side extending in the second direction DR2, embodiments are not limited thereto. For example, the planar shape of the display device 10 (or 10′) may be variously changed according to embodiments.

Following descriptions with reference to the drawings may be substantially equally applied to the display device 10 of FIG. 1A and the display device 10′ of FIG. 1B. Therefore, hereinafter, for convenience of description, the display device 10 and the display device 10′ are referred to as the display device 10 below.

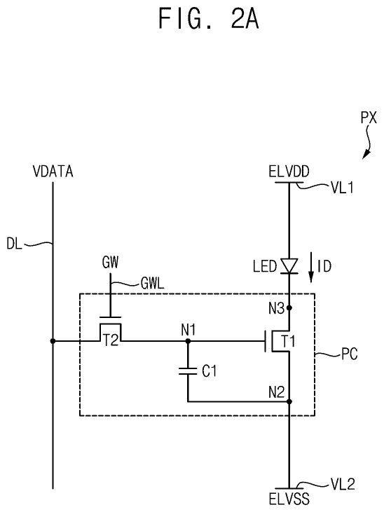

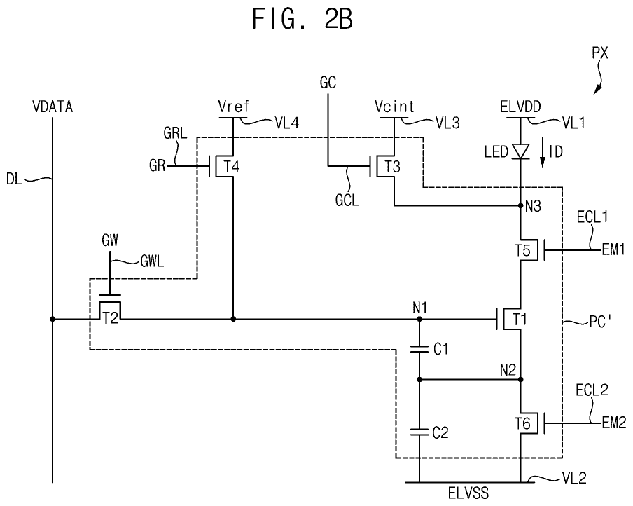

FIG. 2A is a schematic diagram of an equivalent circuit illustrating an example of a circuit structure of a pixel included in the display device of FIGS. 1A and 1B.

Referring to FIG. 2A, the pixel PX may include a light emitting element LED and a pixel driving circuit PC electrically connected to the light emitting element LED. In an embodiment, the pixel driving circuit PC may include a first transistor T1, a second transistor T2, and a first capacitor C1. In FIG. 2A, the first transistor T1 and the second transistor T2 are illustrated as n-type transistors. However, embodiments are not limited thereto, and some of the first transistor T1 and the second transistor T2 may be n-type transistors, and others may be p-type transistors. For example, the first transistor T1 may be an n-type transistor, and the second transistor T2 may be a p-type transistor.

In case that the pixel PX includes an n-type transistor and a p-type transistor, an active pattern of the n-type transistor may include an oxide semiconductor material, and an active pattern of the p-type transistor may include a silicon semiconductor material. However, embodiments are not limited thereto, and the active pattern of the n-type transistor and the active pattern of the p-type transistor may include a silicon semiconductor material.

The pixel driving circuit PC may be electrically connected to a first gate line GWL, a data line DL, a first voltage line VL1, and a second voltage line VL2. The first gate line GWL may transfer a first gate signal GW. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level.

The first transistor T1 may include a gate terminal, a first terminal, and a second terminal. In an embodiment, the first terminal of the first transistor T1 may be a source, and the second terminal of the first transistor T1 may be a drain. The gate terminal of the first transistor T1 may be electrically connected to a first node N1. The first terminal of the first transistor T1 may be electrically connected to a second node N2. The second terminal of the first transistor T1 may be electrically connected to a third node N3. The second terminal of the first transistor T1 may be electrically connected to the light emitting element LED. The first transistor T1 may provide a driving current ID to the light emitting element LED.

The second transistor T2 may include a gate terminal, a first terminal, and a second terminal. In an embodiment, the first terminal of the second transistor T2 may be a source, and the second terminal of the second transistor T2 may be a drain. However, embodiments are not limited thereto, and the first terminal of the second transistor T2 may be a drain, and the second terminal of the second transistor T2 may be a source. The gate terminal of the second transistor T2 may be electrically connected to the first gate line GWL. The first terminal of the second transistor T2 may be electrically connected to the data line DL. The second terminal of the second transistor T2 may be electrically connected to the first node N1.

The gate terminal of the second transistor T2 may receive the first gate signal GW through the first gate line GWL. The second transistor T2 may be turned on or off in response to the first gate signal GW. For example, in case that the second transistor T2 is an n-type transistor, the second transistor T2 may be turned off when the first gate signal GW has a negative voltage level, and may be turned on when the first gate signal GW has a positive voltage level. In case that the second transistor T2 is a p-type transistor, the second transistor T2 may be turned off when the first gate signal GW has a positive voltage level, and may be turned on when the first gate signal GW has a negative voltage level. The first terminal of the second transistor T2 may receive the data voltage VDATA through the data line DL. The second terminal of the second transistor T2 may provide the data voltage VDATA to the first node N1 during a period in which the second transistor T2 is turned on. Accordingly, the second transistor T2 may drive the first transistor T1.

The first capacitor C1 may include a first terminal and a second terminal. The first terminal of the first capacitor C1 may be electrically connected to the first node N1. The second terminal of the first capacitor C1 may be electrically connected to the second node N2. The first capacitor C1 may be charged and discharged depending on the data voltage VDATA transferred to the first node N1.

The light emitting element LED may include an anode and a cathode. The anode of the light emitting element LED may be electrically connected to the first voltage line VL1. The cathode of the light emitting element LED may be electrically connected to the third node N3. For example, the cathode of the light emitting element LED may be electrically connected to the second terminal of the first transistor T1.

FIG. 2B is a schematic diagram of an equivalent circuit illustrating an example of a circuit structure of a pixel included in the display device of FIGS. 1A and 1B.

Referring to FIG. 2B, the pixel PX may include a light emitting element LED and a pixel driving circuit PC′ electrically connected to the light emitting element LED. In an embodiment, the pixel driving circuit PC′ may include a first transistor T1, a second transistor T2, a third transistor T3, a fourth transistor T4, a fifth transistor T5, a sixth transistor T6, a first capacitor C1, and a second capacitor C2. In FIG. 2B, the first, second, third, fourth, fifth, and sixth transistors T1, T2, T3, T4, T5, and T6 are all illustrated as n-type transistors. However, embodiments are not limited thereto, and some of the first, second, third, fourth, fifth, and sixth transistors T1, T2, T3, T4, T5, and T6 may be n-type transistors, and others may be p-type transistors. For example, the first transistor T1 may be an n-type transistor, some of the second to sixth transistors T2, T3, T4, T5, and T6 may be n-type transistors, and others may be p-type transistors.

The pixel driving circuit PC′ may be electrically connected to a first gate line GWL, a second gate line GCL, a third gate line GRL, a data line DL, a first voltage line VL1, a second voltage line VL2, a third voltage line VL3, a fourth voltage line VL4, a first light emitting control line ECL1, and a second light emitting control line ECL2. The first gate line GWL may transfer a first gate signal GW. The second gate line GCL may transfer a second gate signal GC. The third gate line GRL may transfer a third gate signal GR. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level. The third voltage line VL3 may transfer an initialization voltage Vcint. The fourth voltage line VL4 may transfer a reference voltage Vref. The reference voltage Vref may have a voltage level lower than a voltage level of the first power voltage ELVDD.

The first transistor T1 may include a gate terminal, a first terminal, and a second terminal. The gate terminal of the first transistor T1 may be electrically connected to a first node N1. The first terminal of the first transistor T1 may be electrically connected to a second node N2. The second terminal of the first transistor T1 may be electrically connected to the fifth transistor T5. The second terminal of the first transistor T1 may be electrically connected to the light emitting element LED through the fifth transistor T5. The first transistor T1 may provide a driving current ID to the light emitting element LED.

The second transistor T2 may include a gate terminal, a first terminal, and a second terminal. The gate terminal of the second transistor T2 may be electrically connected to the first gate line GWL. The first terminal of the second transistor T2 may be electrically connected to the data line DL. The second terminal of the second transistor T2 may be electrically connected to the first node N1.

The gate terminal of the second transistor T2 may receive the first gate signal GW through the first gate line GWL. The second transistor T2 may be turned on or off in response to the first gate signal GW. The first terminal of the second transistor T2 may receive the data voltage VDATA through the data line DL. The second terminal of the second transistor T2 may provide the data voltage VDATA to the first node N1 during a period in which the second transistor T2 is turned on. Accordingly, the second transistor T2 may drive the first transistor T1.

The third transistor T3 may include a gate terminal, a first terminal, and a second terminal. In an embodiment, the first terminal of the third transistor T3 may be a source, and the second terminal of the third transistor T3 may be a drain. However, embodiments are not limited thereto, and the first terminal of the third transistor T3 may be a drain, and the second terminal of the third transistor T3 may be a source. The gate terminal of the third transistor T3 may be electrically connected to the second gate line GCL. The first terminal of the third transistor T3 may be electrically connected to a third node N3. The second terminal of the third transistor T3 may be electrically connected to the third voltage line VL3.

The gate terminal of the third transistor T3 may receive the second gate signal GC through the second gate line GCL. The third transistor T3 may be turned on or off in response to the second gate signal GC. For example, in case that the third transistor T3 is an n-type transistor, the third transistor T3 may be turned off when the second gate signal GC has a negative voltage level, and may be turned on when the second gate signal GC has a positive voltage level. In case that the third transistor T3 is a p-type transistor, the third transistor T3 may be turned off when the second gate signal GC has a positive voltage level, and may be turned on when the second gate signal GC has a negative voltage level. During a period in which the third transistor T3 is turned on, the third transistor T3 may provide the initialization voltage Vcint to the third node N3. For example, the third transistor T3 may provide the initialization voltage Vcint to a cathode of the light emitting element LED in response to the second gate signal GC to initialize a voltage of the cathode.

The fourth transistor T4 may include a gate terminal, a first terminal, and a second terminal. In an embodiment, the first terminal of the fourth transistor T4 may be a source, and the second terminal of the fourth transistor T4 may be a drain. However, embodiments are not limited thereto, and the first terminal of the fourth transistor T4 may be a drain, and the second terminal of the fourth transistor T4 may be a source. The gate terminal of the fourth transistor T4 may be electrically connected to the third gate line GRL. The first terminal of the fourth transistor T4 may be electrically connected to the first node N1. The second terminal of the fourth transistor T4 may be electrically connected to the fourth voltage line VL4.

The gate terminal of the fourth transistor T4 may receive the third gate signal GR through the third gate line GRL. The fourth transistor T4 may be turned on or off in response to the third gate signal GR. For example, in case that the fourth transistor T4 is an n-type transistor, the fourth transistor T4 may be turned off when the third gate signal GR has a negative voltage level, and may be turned on when the third gate signal GR has a positive voltage level. In case that the fourth transistor T4 is a p-type transistor, the fourth transistor T4 may be turned off when the third gate signal GR has a positive voltage level, and may be turned on when the third gate signal GR has a negative voltage level. During a period in which the fourth transistor T4 is turned on, the fourth transistor T4 may provide the reference voltage Vref to the first node N1. The fifth transistor T5 may include a gate terminal, a first terminal, and a second terminal. In an embodiment, the first terminal of the fifth transistor T5 may be a source, and the second terminal of the fifth transistor T5 may be a drain. However, embodiments are not limited thereto, and the first terminal of the fifth transistor T5 may be a drain, and the second terminal of the fifth transistor T5 may be a source. The gate terminal of the fifth transistor T5 may be electrically connected to the first light emitting control line ECL1. The first terminal of the fifth transistor T5 may be electrically connected to the second terminal of the first transistor T1. The second terminal of the fifth transistor T5 may be electrically connected to the third node N3. The second terminal of the fifth transistor T5 may be electrically connected to the light emitting element LED.

The gate terminal of the fifth transistor T5 may receive the first light emitting control signal EM1 through the first light emitting control line ECL1. The fifth transistor T5 may be turned on or off in response to the first light emitting control signal EM1. For example, in case that the fifth transistor T5 is an n-type transistor, the fifth transistor T5 may be turned off when the first light emitting n control signal EM1 has a negative voltage level, and may be turned on when the first light emitting control signal EM1 has a positive voltage level. In case that the fifth transistor T5 is a p-type transistor, the fifth transistor T5 may be turned off when the first light emitting control signal EM1 has a positive voltage level, and may be turned on when the first light emitting control signal EM1 has a negative voltage level. During a period in which the fifth transistor T5 is turned on, the fifth transistor T5 may electrically connect the first transistor T1 to the light emitting element LED. For example, in case that the fifth transistor T5 is turned on, the first transistor T1 may be electrically connected to the light emitting element LED through the fifth transistor T5. For example, the fifth transistor T5 may electrically connect the second terminal of the first transistor T1 to the cathode of the light emitting element LED in response to the first light emitting control signal EM1.

The sixth transistor T6 may include a gate terminal, a first terminal, and a second terminal. In an embodiment, the first terminal of the sixth transistor T6 may be a source, and the second terminal of the sixth transistor T6 may be a drain. However, embodiments are not limited thereto, and the first terminal of the sixth transistor T6 may be a drain, and the second terminal of the sixth transistor T6 may be a source. The gate terminal of the sixth transistor T6 may be electrically connected to the second light emitting control line ECL2. The first terminal of the sixth transistor T6 may be electrically connected to the second voltage line VL2. The second terminal of the sixth transistor T6 may be electrically connected to the second node N2.

The gate terminal of the sixth transistor T6 may receive the second light emitting control signal EM2 through the second light emitting control line ECL2. The sixth transistor T6 may be turned on or off in response to the second light emitting control signal EM2. For example, in case that the sixth transistor T6 is an n-type transistor, the sixth transistor T6 may be turned off when the second light emitting control signal EM2 has a negative voltage level, and may be turned on when the second light emitting control signal EM2 has a positive voltage level. In case that the sixth transistor T6 is a p-type transistor, the sixth transistor T6 may be turned off when the second light emitting control signal EM2 has a positive voltage level, and may be turned on when the second light emitting control signal EM2 has a negative voltage level. During a period in which the sixth transistor T6 is turned on, the sixth transistor T6 may provide the second power voltage ELVSS to the second node N2.

Although FIG. 2B illustrates the fifth transistor T5 and the sixth transistor T6 independently driven by different light emitting control signals (e.g., the first and second light emitting control signals EM1 and EM2), embodiments are not limited thereto. For example, the first light emitting control signal EM1 and the second light emitting control signal EM2 may be provided as a substantially single light emitting control signal, and the fifth transistor T5 and the sixth transistor T6 may be simultaneously turned on or off. The light emitting control line ECL1 and the second light emitting control line ECL2 may be provided as a substantially single light emitting control line.

The first capacitor C1 may include a first terminal and a second terminal. The first terminal of the first capacitor C1 may be electrically connected to the first node N1. The second terminal of the first capacitor C1 may be electrically connected to the second node N2. The first capacitor C1 may be charged and discharged depending on the data voltage VDATA transferred to the first node N1.

The second capacitor C2 may include a first terminal and a second terminal. The first terminal of the second capacitor C2 may be electrically connected to the second node N2. The second terminal of the second capacitor C2 may be electrically connected to the second voltage line VL2. For example, the second capacitor C2 may be electrically connected to the first capacitor C1 in series. The data voltage VDATA may be transferred to the first node N1, and due to the serial connection between the first capacitor C1 and the second capacitor C2, the data voltage VDATA may be voltage-divided and transferred to the second node N2. Since the first transistor T1 generates the driving current ID based on a voltage of the first node N1 and a voltage of the second node N2, a data range may be extended.

The light emitting element LED may include an anode and the cathode. The anode of the light emitting element LED may be electrically connected to the first voltage line VL1. The cathode of the light emitting element LED may be electrically connected to the third node N3. For example, the cathode of the light emitting element LED may be electrically connected to the second terminal of the first transistor T1 through the fifth transistor T5.

As illustrated in FIGS. 2A and 2B, according to embodiments, the anode of the light emitting element LED may receive the first power voltage ELVDD through the first voltage line VL1, and the cathode of the light emitting element LED may be electrically connected to the second terminal of the first transistor T1. For example, a potential of the cathode of the light emitting element LED may be controlled by being electrically connected to the first transistor T1. For example, the first transistor T1 may control the potential of the cathode of the light emitting element LED.

Since the first voltage line VL1 provides the first power voltage ELVDD having a relatively high voltage level, and the second voltage line VL2 provides the second power voltage ELVSS having a relatively low voltage level, in case that the first transistor T1 is an n-type transistor, the second terminal of the first transistor T1 may be a drain. For example, the first transistor T1 may be the n-type transistor having the second terminal of the drain, and the first and second voltage lines VL1 and VL2 may apply the first power voltage ELVDD and the second power voltage ELVSS having a smaller voltage level. For example, according to embodiments, the cathode of the light emitting element LED may be electrically connected to the drain of the first transistor T1.

In case that the first transistor T1 is an n-type transistor and the anode of the light emitting element LED is electrically connected to the source of the first transistor T1, a source voltage of the first transistor T1 may shift due to deterioration of the light emitting element LED. Thus, a gate-source voltage (Vgs) of the first transistor T1 may change. Accordingly, a range of change in the driving current ID may increase, an after-image defect may occur, and a lifespan of the display device may be reduced.

According to embodiments, the anode of the light emitting element LED may receive the first power voltage ELVDD, and the cathode of the light emitting element LED may be electrically connected to the drain of the first transistor T1. Accordingly, even when the light emitting element LED deteriorates, the gate-source voltage of the first transistor T1 may not change, and the range of change in the driving current ID due to the deterioration of the light emitting element LED may be reduced. Accordingly, the after-image defect of the display device DD depending on an increase in time of use may be reduced, and the lifespan of the display device DD may be improved.

The circuit structures of the pixel (e.g., the number or arrangement relationship of transistors, the number or arrangement relationship of capacitors, or the like) illustrated in FIGS. 2A and 2B is merely examples, and may be variously changed according to embodiments.

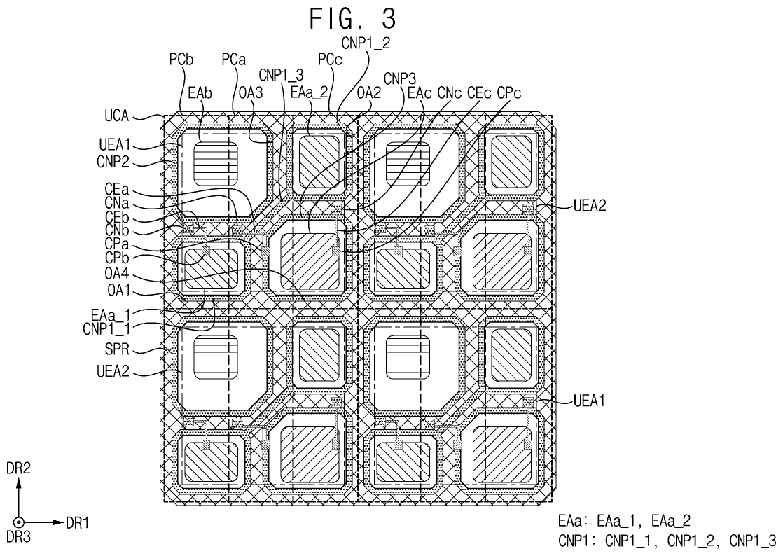

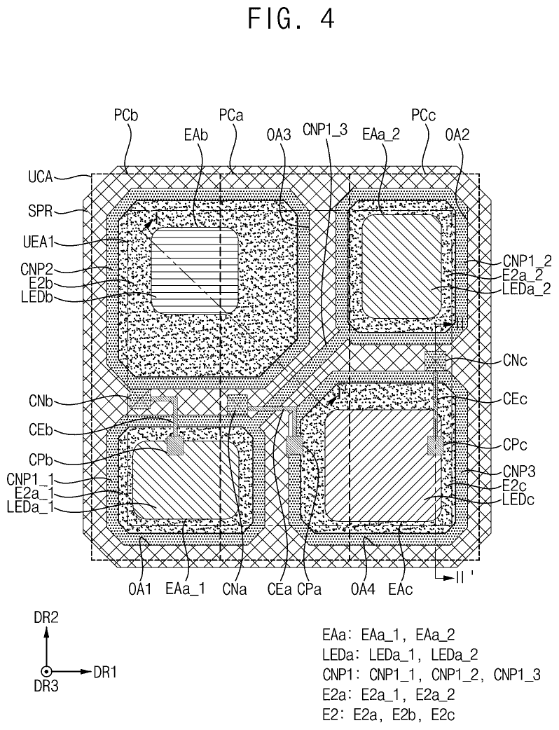

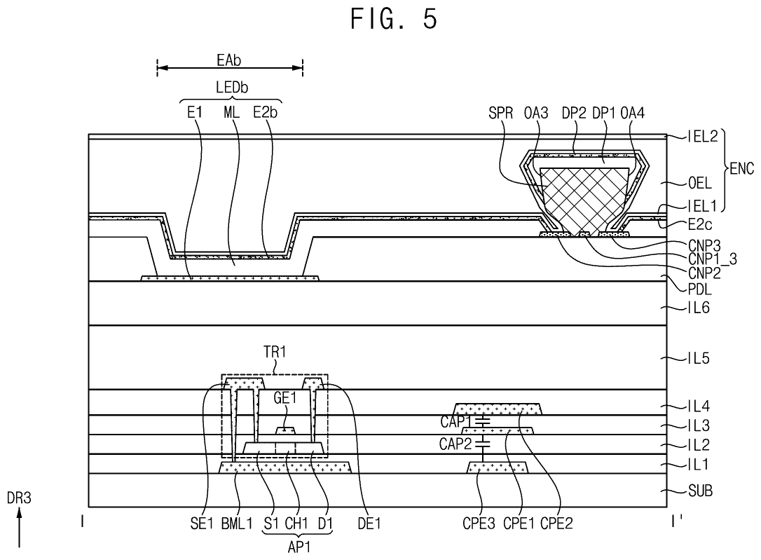

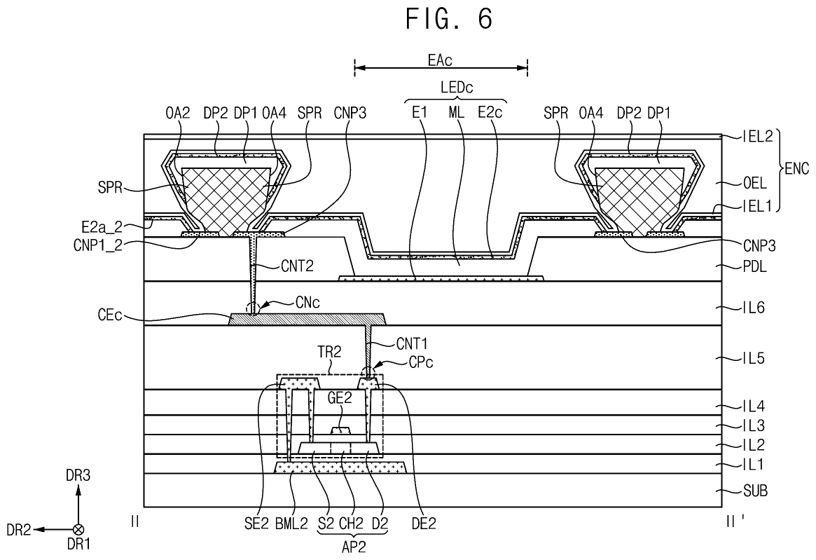

FIG. 3 is a schematic plan view schematically illustrating a portion of the display device of FIGS. 1A and 1B. FIG. 4 is a schematic enlarged view illustrating a portion of FIG. 3. FIG. 5 is a schematic cross-sectional view taken along line I-I′ of FIG. 4. FIG. 6 is a schematic cross-sectional view taken along line II-II′ of FIG. 4.

For example, FIG. 3 illustrates an area in which four unit light emitting areas UEA1 and UEA2 forming a matrix of two rows and two columns are arranged, and FIG. 4 illustrates an enlarged view of a first unit light emitting area UEA1 among the unit light emitting areas UEA1 and UEA2. For convenience of description, some of components illustrated in FIGS. 5 and 6 are omitted or emphasized in FIGS. 3 and 4. A second electrode layer E2 among components illustrated in FIG. 4 is omitted in FIG. 3.

Referring to FIGS. 3 and 4, the display device 10 may include a first pixel driving circuit PCa, a second pixel driving circuit PCb, a third pixel driving circuit PCc, a first light emitting element LEDa, a second light emitting element LEDb, a third light emitting element LEDc, a first connection electrode CEa, a second connection electrode CEb, a third connection electrode CEc, a first connection pattern CNP1, a second connection pattern CNP2, a third connection pattern CNP3, and a separator SPR.

Each of the first, second, and third pixel driving circuits PCa, PCb, and PCc may correspond to at least one of the pixel driving circuits PC and PC′ described with reference to FIGS. 2A and 2B. For example, each of the first, second, and third pixel driving circuits PCa, PCb, and PCc may include at least one transistor and at least one capacitor. For example, each of the first, second, and third pixel driving circuits PCa, PCb, and PCc may include a first transistor TR1, a second transistor TR2, a first capacitor CAP1, and a second capacitor CAP2 illustrated in FIGS. 5 and 6.

The second transistor TR2 may be a transistor electrically connected to the light emitting element through a connection electrode and a connection pattern. For example, in case that each of the first, second, and third pixel driving circuits PCa, PCb, and PCc is the pixel driving circuit PC of FIG. 2A, the first transistor TR1 may be the second transistor T2 of FIG. 2A, and the second transistor TR2 may be the first transistor T1 of FIG. 2A. For another example, in case that each of the first, second, and third pixel driving circuits PCa, PCb, and PCc is the pixel driving circuit PC′ of FIG. 2B, the first transistor TR1 may be one of the first, second, third, fourth, and sixth transistors T1, T2, T3, T4, and T6 of FIG. 2B, and the second transistor TR2 may be the fifth transistor T5 of FIG. 2B. However, embodiments are not limited thereto.

In an embodiment, the first capacitor CAP1 may correspond to the first capacitor C1 of FIGS. 2A and 2B, and the second capacitor CAP2 may correspond to the second capacitor C2 of FIG. 2B. For example, in case that each of the first, second, and third pixel driving circuits PCa, PCb, and PCc is the pixel driving circuit PC of FIG. 2A, the second capacitor CAP2 may be omitted. However, embodiments are not limited thereto, and in an embodiment, the first capacitor CAP1 may correspond to the second capacitor C2 of FIG. 2B, and the second capacitor CAP2 may correspond to the first capacitor C1 of FIGS. 2A and 2B. In case that each of the first, second, and third pixel driving circuits PCa, PCb, and PCc is the pixel driving circuit PC of FIG. 2A, the first capacitor CAP1 may be omitted.

The first transistor TR1, the second transistor TR2, the first capacitor CAP1, and the second capacitor CAP2 will be described in more detail with reference to FIGS. 5 and 6.

Each of the first, second, and third light emitting elements LEDa, LEDb, and LEDc may correspond to the light emitting element LED described with reference to FIGS. 2A and 2B. At least one of the first, second, and third light emitting elements LEDa, LEDb, and LEDc may include sub-elements spaced apart from each other. In an embodiment, the first light emitting element LEDa may include sub-elements spaced apart from each other. The first light emitting element LEDa may include a first sub-element LEDa_1 and a second sub-element LEDa_2, which are spaced apart from each other.

For example, each of the first, second, and third light emitting elements LEDa, LEDb, and LEDc may include a first electrode (e.g., a first electrode E1 of FIGS. 5 and 6), an intermediate layer (e.g., an intermediate layer ML of FIGS. 5 and 6), and a second electrode layer E2 disposed on the intermediate layer. In an embodiment, the first electrode E1 may function as the anode of FIGS. 2A and 2B, and the second electrode layer E2 may function as the cathode of FIGS. 2A and 2B.

In an embodiment, the second electrode layer E2 may be separated (or disconnected) into second electrodes E2a, E2b, and E2c by the separator SPR. For example, the second electrode layer E2 may be separated (or disconnected) into a second electrode E2a of the first light emitting element LEDa, a second electrode E2b of the second light emitting element LEDb, and a second electrode E2c of the third light emitting element LEDc. The second electrode E2a of the first light emitting element LEDa may be separated (or disconnected) into a second electrode E2a_1 of the first sub-element LEDa_1 and a second electrode E2a_2 of the second sub-element LEDa_2. For example, the second electrode layer E2 may be separated (or disconnected) into the second electrodes E2a_1, E2a_2, E2b, and E2c by the separator SPR, and the second electrodes E2a_1, E2a_2, E2b, and E2c may be electrically insulated from each other. This will be described in more detail later.

The first, second, and third light emitting elements LEDa, LEDb, and LEDc may emit light of different colors. For example, the first light emitting element LEDa may emit red light, the second light emitting element LEDb may emit green light, and the third light emitting element LEDc may emit blue light. The first and second sub-elements LEDa_1 and LEDa_2 of the first light emitting element LEDa may emit red light, respectively. However, embodiments are not limited thereto.

The first, second, and third light emitting elements LEDa, LEDb, and LEDc may be respectively connected to one of the first, second, and third pixel driving circuits PCa, PCb, and PCc. The first light emitting element LEDa may be electrically connected to the first pixel driving circuit PCa, the second light emitting element LEDb may be electrically connected to the second pixel driving circuit PCb, and the third light emitting element LEDc may be electrically connected to the third pixel driving circuit PCc. The first pixel driving circuit PCa may be electrically connected to the first and second sub-elements LEDa_1 and LEDa_2 of the first light emitting element LEDa.

Accordingly, the first pixel driving circuit PCa and the first light emitting element LEDa may form a pixel PX (e.g., refer to FIGS. 1A and 1B), the second pixel driving circuit PCb and the second light emitting element LEDb may form a pixel PX (e.g., refer to FIGS. 1A and 1B), and the third pixel driving circuit PCc and the third light emitting element LEDc may form a pixel PX (e.g., refer to FIGS. 1A and 1B). The first pixel driving circuit PCa and the first sub-element LEDa_1 of the first light emitting element LEDa may form a sub-pixel, and the first pixel driving circuit PCa and the second sub-element LEDa_2 of the first light emitting element LEDa may form a sub-pixel.

In an embodiment, a pixel driving circuit electrically connected to a light emitting element including sub-elements may be disposed between pixel driving circuits electrically connected to other light emitting elements in a plan view. For example, the first pixel driving circuit PCa electrically connected to the first light emitting element LEDa including the first and second sub-elements LEDa_1 and LEDa_2 may be disposed between the second pixel driving circuit PCb electrically connected to the second light emitting element LEDb and the third pixel driving circuit PCc electrically connected to the third light emitting element LEDc in a plan view. For example, the first pixel driving circuit PCa may be adjacent to the second pixel driving circuit PCb in the first direction DR1, and the third pixel driving circuit PCc may be adjacent to the first pixel driving circuit PCa in the first direction DR1. The second pixel driving circuit PCb, the first pixel driving circuit PCa, and the third pixel driving circuit PCc may be sequentially arranged along the first direction DR1.

The second pixel driving circuit PCb, the first pixel driving circuit PCa, and the third pixel driving circuit PCc, which are sequentially arranged along the first direction DR1, may define a circuit area (e.g., a unit circuit area) UCA. For example, the unit circuit area UCA may be defined as a substantially rectangular planar shape. The unit circuit area UCA may be defined in a matrix form along the first direction DR1 and the second direction DR2. Although FIG. 3 illustrates four unit circuit areas, the unit circuit areas may be defined in a matrix form along the first direction DR1 and the second direction DR2 in a display area (e.g., the display area DA of FIGS. 1A and 1B).

Although FIGS. 3 and 4 illustrate the first, second, and third pixel driving circuits PCa, PCb, and PCc each having a rectangular planar shape, embodiments are not limited thereto, and the shapes of the first, second, and third pixel driving circuits PCa, PCb, and PCc may be variously changed according to embodiments.

In an embodiment, the display device 10 may include a first unit light emitting area (e.g., a first light emitting area group) UEA1 and a second unit light emitting area (e.g., a second light emitting area group) UEA2. The first unit light emitting area UEA1 and the second unit light emitting area UEA2 may be defined in a matrix form along the first direction DR1 and the second direction DR2. Although FIG. 3 illustrates four unit light emitting areas, the unit light emitting areas may be defined in a matrix form along the first direction DR1 and the second direction DR2 in the display area (e.g., the display area DA of FIGS. 1A and 1B).

The first, second, and third light emitting elements LEDa, LEDb, and LEDc adjacent to each other may be disposed in each of the first and second unit light emitting areas UEA1 and UEA2. For example, first, second, and third light emitting areas EAa, EAb, and EAc adjacent to each other may be defined in each of the first and second unit light emitting areas UEA1 and UEA2.

The first, second, and third light emitting areas EAa, EAb, and EAc may be defined by pixel openings of a pixel defining layer (e.g., a pixel defining layer PDL of FIGS. 5 and 6). The first, second, and third light emitting elements LEDa, LEDb, and LEDc may be disposed in the first, second, and third light emitting areas EAa, EAb, and EAc, respectively. Each of the first, second, and third light emitting areas EAa, EAb, and EAc may be an area in which light is emitted by a light emitting element.

For example, the first light emitting element LEDa may be disposed in the first light emitting area EAa, and the first light emitting area EAa may be an area in which light is emitted by the first light emitting element LEDa. The second light emitting element LEDb may be disposed in the second light emitting area EAb, and the second light emitting area EAb may be an area in which light is emitted by the second light emitting element LEDb. The third light emitting element LEDc may be disposed in the third light emitting area EAc, and the third light emitting area EAc may be an area in which light is emitted by the third light emitting element LEDc.

In an embodiment, the first light emitting area EAa may include sub-areas spaced apart from each other. The first light emitting area EAa may include a first sub-area EAa_1 and a second sub-area EAa_2, which are spaced apart from each other. The first and second sub-elements LEDa_1 and LEDa_2 of the first light emitting element LEDa may be disposed in the first and second sub-areas EAa_1 and EAa_2 of the first light emitting area LEDa, respectively. For example, the first sub-element LEDa_1 may be disposed in the first sub-area EAa_1, and the first sub-area EAa_1 may be an area in which light is emitted by the first sub-element LEDa_1. The second sub-element LEDa_2 may be disposed in the second sub-area EAa_2, and the second sub-area EAa_2 may be an area in which light is emitted by the second sub-element LEDa_2.

In an embodiment, the first unit light emitting area UEA1 and the second unit light emitting area UEA2 may be distinguished based on an arrangement relationship between the first, second, and third light emitting elements LEDa, LEDb, and LEDc (or an arrangement relationship between the first, second, and third light emitting areas EAa, EAb, and EAc). For example, the arrangement relationship between the first, second, and third light emitting elements LEDa, LEDb, and LEDc (or the first, second, and third light emitting areas EAa, EAb, and EAc) may be the same for each first unit light emitting area UEA1, and the arrangement relationship between the first, second, and third light emitting elements LEDa, LEDb, and LEDc (or the first, second, and third light emitting areas EAa, EAb, and EAc) may be the same for each second unit light emitting area UEA2. For example, the first, second, and third light emitting elements LEDa, LEDb, and LEDc (or the first, second, and third light emitting areas EAa, EAb, and EAc) in each first unit light emitting area UEA1 may have a same arrangement relationship, and the first, second, and third light emitting elements LEDa, LEDb, and LEDc (or the first, second, and third light emitting areas EAa, EAb, and EAc) in each second unit light emitting area UEA2 may have a same arrangement relationship.

FIG. 3 illustrates the first, second, and third light emitting elements LEDa, LEDb, and LEDc (or the first, second, and third light emitting areas EAa, EAb, and EAc) having a same arrangement relationship in the first unit light emitting area UEA1 and the second unit light emitting area UEA2. However, embodiments are not limited thereto, and the arrangement relationships between the first, second, and third light emitting elements LEDa, LEDb, and LEDc (or the first, second, and third light emitting areas EAa, EAb, and EAc) in the first unit light emitting area UEA1 and the second unit light emitting area UEA2 may be variously changed according to embodiments.

As illustrated in FIG. 3, in an embodiment, the first unit light emitting area UEA1 and the second unit light emitting area UEA2 may be alternately arranged along the first direction DR1 (i.e., a row direction) and the second direction DR2 (i.e., a column direction). For example, each of the first and second unit light emitting areas UEA1 and UEA2 may be defined as a substantially rectangular planar shape. However, embodiments are not limited thereto, and the number of different unit light emitting areas included in the display device 10, an arrangement relationship between the unit light emitting areas, a shape of the unit light emitting area, or the like may be variously changed according to embodiments.

In an embodiment, in the first and second unit light emitting areas UEA1 and UEA2, the second sub-element LEDa_2 (or the second sub-area EAa_2) may be spaced apart from the first sub-element LEDa_1 (or the first sub-area EAa_1) in a direction between the first direction DR1 and the second direction DR2 (e.g., a diagonal direction between the first and second directions DR1 and DR2), the second light emitting element LEDb (or the second light emitting area EAb) may be spaced apart from the first sub-element LEDa_1 (or the first sub-area EAa_1) in the second direction DR2, and the third light emitting element LEDc (or the third light emitting area EAc) may be spaced apart from the first sub-element LEDa_1 (or the first sub-area EAa_1) in the first direction DR1. For example, the first sub-element LEDa_1 (or the first sub-area EAa_1) and the second sub-element LEDa_2 (or the second sub-area EAa_2) may be arranged in a diagonal direction between the first and second directions DR1 and DR2. The first sub-element LEDa_1 (or the first sub-area EAa_1) and the second light emitting element LEDb (or the second light emitting area EAb) may be arranged in the second direction DR2. The third light emitting element LEDc (or the third light emitting area EAc) and the first sub-element LEDa_1 (or the first sub-area EAa_1) may be arranged in the first direction DR1. In an embodiment, the first sub-element LEDa_1 (or the first sub-area EAa_1) may overlap the second pixel driving circuit PCb in a plan view, and the second sub-element LEDa_2 (or the second sub-area EAa_2) may overlap the third pixel driving circuit PCc in a plan view. For example, at least a portion of each of the first sub-element LEDa_1 (or the first sub-area EAa_1) and the second light emitting element LEDb (or the second light emitting area EAb) may overlap the second pixel driving circuit PCb in a plan view, and at least a portion of each of the second sub-element LEDa_2 (or the second sub-area EAa_2) and the third light emitting element LEDc (or the third light emitting area EAc) may overlap the third pixel driving circuit PCc in a plan view.

However, embodiments are not limited thereto, and an arrangement of the first, second, and third light emitting elements LEDa, LEDb, and LEDc (or the first, second, and third light emitting areas EAa, EAb, and EAc) may be variously changed according to embodiments.

The first and second unit light emitting areas UEA1 and UEA2 may correspond to the unit circuit areas UCA, respectively. The first unit light emitting area UEA1 and the unit circuit area UCA may form a unit pixel, and the second unit light emitting area UEA2 and the unit circuit area UCA may form a unit pixel. The unit pixel may include the pixel formed by the first pixel driving circuit PCa and the first light emitting element LEDa (i.e., the sub-pixels formed by the first pixel driving circuit PCa and the first and second sub-elements LEDa_1 and LEDa_2, respectively), the pixel formed by the second pixel driving circuit PCb and the second light emitting element LEDb, and the pixel formed by the third pixel driving circuit PCc and the third light emitting element LEDc. For example, each of the sub-pixels may be formed by the first pixel driving circuit PCa and each of the first and second sub-elements LEDa_1 and LEDa_2.

In an embodiment, each of the first and second unit light emitting areas UEA1 and UEA2 may overlap the unit circuit area UCA in a plan view. For example, each first unit light emitting area UEA1 may overlap each unit circuit area UCA as a whole in a plan view, and each second unit light emitting area UEA2 may overlap each unit circuit area UCA as a whole in a plan view.

Hereinafter, the first unit light emitting area UEA1 of FIG. 4 is described, and a connection relationship between the first, second, and third light emitting elements LEDa, LEDb, and LEDc and the first, second, and third pixel driving circuits PCa, PCb, and PCc will be described in more detail. The following description of the connection relationship between the first, second, and third light emitting elements LEDa, LEDb, and LEDc and the first, second, and third pixel driving circuits PCa, PCb, and PCc may be substantially equally applied to all unit light emitting areas.

As described above, the display device 10 may include the first, second, and third connection electrodes CEa, CEb, and CEc and the first, second, and third connection patterns CNP1, CNP2, and CNP3. In an embodiment, the first connection electrode CEa and the first connection pattern CNP1 may electrically connect the first light emitting element LEDa to the first pixel driving circuit PCa, the second connection electrode CEb and the second connection pattern CNP2 may electrically connect the second light emitting element LEDb to the second pixel driving circuit PCb, and the third connection electrode CEc and the third connection pattern CNP3 may electrically connect the third light emitting element LEDc to the third pixel driving circuit PCc. For example, the first light emitting element LEDa may be electrically connected to the first pixel driving circuit PCa through the first connection electrode CEa and the first connection pattern CNP1, the second light emitting element LEDb may be electrically connected to the second pixel driving circuit PCb through the second connection electrode CEb and the second connection pattern CNP2, and the third light emitting element LEDc may be electrically connected to the third pixel driving circuit PCc through the third connection electrode CEc and the third connection pattern CNP3.

The first, second, and third connection electrodes CEa, CEb, and CEc may include a conductive material such as a metal, an alloy, a conductive metal oxide, a conductive metal nitride, a transparent conductive oxide, or the like. Examples of the conductive material that may be used as the first, second, and third connection electrodes CEa, CEb, and CEc may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy including aluminum, an alloy including silver, an alloy including copper, an alloy including molybdenum, aluminum nitride (AlN), tungsten nitride (WN), chromium nitride (TiN), tantalum nitride (TaN), indium gallium zinc oxide (IGZO), indium tin oxide (ITO), indium gallium zinc oxide (IZO), indium gallium oxide (IGO), indium oxide (InO), tin oxide (SnO), gallium oxide (GaO), aluminum zinc oxide (AZO), or the like. These may be used alone or in combination with each other.

In an embodiment, each of the first, second, and third connection electrodes CEa, CEb, and CEc may have a single-layer structure or a multi-layer structure in which conductive layers are stacked each other.

In an embodiment, the first, second, and third connection patterns CNP1, CNP2, and CNP3 may include a transparent conductive oxide. Examples of the transparent conductive oxide that may be used as the first, second, and third connection patterns CNP1, CNP2, and CNP3 may include indium gallium zinc oxide, indium tin oxide, indium zinc oxide, indium gallium oxide, zinc oxide, indium oxide, tin oxide, gallium oxide, aluminum zinc oxide, or the like. These may be used alone or in combination with each other.

However, embodiments are not limited thereto, and in an embodiment, the first, second, and third connection patterns CNP1, CNP2, and CNP3 may include a conductive material such as a metal, an alloy, a conductive metal nitride, or the like. Examples of the conductive material that may be used as the first, second, and third connection patterns CNP1, CNP2, and CNP3 may include gold, silver, aluminum, platinum, nickel, titanium, palladium, magnesium, lithium, chromium, tantalum, tungsten, copper, molybdenum, scandium, neodymium, iridium, an alloy including aluminum, an alloy including silver, an alloy including copper, an alloy including molybdenum, aluminum nitride, tungsten nitride, titanium nitride, chromium nitride, tantalum nitride, or the like. These may be used alone or in combination with each other.

In an embodiment, each of the first, second, and third connection patterns CNP1, CNP2, and CNP3 may have a single-layer structure or a multi-layer structure in which conductive layers are stacked each other.

In an embodiment, the first connection electrode CEa may overlap the first pixel driving circuit PCa in a plan view. For example, the first connection electrode CEa may not overlap the second pixel driving circuit PCb or the third pixel driving circuit PCc in a plan view. The first connection electrode CEa may include a first circuit connection portion CPa and a first light emitting connection portion CNa.

The first circuit connection portion CPa may be a portion of the first connection electrode CEa that is electrically connected to the first pixel driving circuit PCa. For example, the first circuit connection portion CPa may be a portion of the first connection electrode CEa that is electrically connected to a second transistor (e.g., a second transistor TR2 of FIG. 6) of the first pixel driving circuit PCa. Accordingly, a position of the first circuit connection portion CPa may correspond to a position of the second transistor of the first pixel driving circuit PCa. For example, the position of the first circuit connection portion CPa may correspond to a position of a first contact hole (e.g., a first contact hole CNT1 of FIG. 6) that exposes the second transistor of the first pixel driving circuit PCa and penetrates a fifth insulating layer (e.g., a fifth insulating layer IL5 of FIG. 6).

The first light emitting connection portion CNa may be a portion of the first connection electrode CEa that is electrically connected to the first connection pattern CNP1. For example, the first light emitting connection portion CNa may be a portion of the first connection electrode CEa that is exposed and electrically connected to the first connection pattern CNP1. Accordingly, a position of the first light emitting connection portion CNa may correspond to a position of a second contact hole (e.g., a second contact hole CNT2 of FIG. 6) that exposes the first connection electrode CEa and penetrates a pixel defining layer (e.g., a pixel defining layer PDL of FIG. 6) and a sixth insulating layer (e.g., a sixth insulating layer IL6 of FIG. 6). The first light emitting connection portion CNa may not overlap the first light emitting area EAa in a plan view. For example, the first light emitting connection portion CNa may overlap the separator SPR in a plan view, and may be disposed below the separator SPR.

The first connection pattern CNP1 may be electrically connected to the first connection electrode CEa. For example, the first connection pattern CNP1 may contact (or may be electrically connected to) the first light emitting connection portion CNa of the first connection electrode CEa. The first connection pattern CNP1 may not overlap the first light emitting area EAa in a plan view. The first connection pattern CNP1 may include a first sub-pattern CNP1_1, a second sub-pattern CNP1_2, and a third sub-pattern CNP1_3. The first, second, and third sub-patterns CNP1_1, CNP1_2, and CNP1_3 may be electrically connected to each other. For example, the third sub-pattern CNP1_3 may extend from the first sub-pattern CNP1_1 to the second sub-pattern CNP1_2.

In an embodiment, the first connection pattern CNP1 may be electrically connected to the first connection electrode CEa through at least one of the first, second, and third sub-patterns CNP1_1, CNP1_2, and CNP1_3. For example, the first sub-pattern CNP1_1 may contact (or may be electrically connected to) the first light emitting connection portion CNa of the first connection electrode CEa, and the second and third sub-patterns CNP1_2 and CNP1_3 may be electrically connected to the first connection electrode CEa through the first sub-pattern CNP1_1.

In an embodiment, the first connection pattern CNP1 may be adjacent to (e.g., surround) at least a portion of the first light emitting area EAa in a plan view. For example, the first sub-pattern CNP1_1 may be a portion of the first connection pattern CNP1 that surrounds at least a portion of the first sub-area EAa_1 in a plan view, the second sub-pattern CNP1_2 may be a portion of the first connection pattern CNP1 that surrounds at least a portion of the second sub-area EAa_2 in a plan view, and the third sub-pattern CNP1_3 may be a portion of the first connection pattern CNP1 that electrically connects the first sub-pattern CNP1_1 and the second sub-pattern CNP1_2. For example, the first sub-pattern CNP1_1 may have a closed ring shape that surrounds the first sub-area EAa_1 as a whole in a plan view, the second sub-pattern CNP1_2 may have a closed ring shape that surrounds the second sub-area EAa_2 as a whole in a plan view, and the third sub-pattern CNP1_3 may have a shape that extends in a direction between the first direction DR1 and the second direction DR2 (e.g., a diagonal direction between the first and second directions DR1 and DR2) in a plan view. However, embodiments are not limited thereto.

The second electrode E2a of the first light emitting element LEDa may be electrically connected to the first connection pattern CNP1. For example, the second electrode E2a of the first light emitting element LEDa may contact (or may be electrically connected to) the first connection pattern CNP1. The second electrode E2a_1 of the first sub-element LEDa_1 may be electrically connected to the first sub-pattern CNP1_1, and the second electrode E2a_2 of the second sub-element LEDa_2 may be electrically connected to the second sub-pattern CNP1_2. For example, the second electrode E2a_1 of the first sub-element LEDa_1 may contact (or may be electrically connected to) the first sub-pattern CNP1_1, and the second electrode E2a_2 of the second sub-element LEDa_2 may contact (or may be electrically connected to) the second sub-pattern CNP1_2.

Accordingly, the first connection pattern CNP1 may electrically connect the first connection electrode CEa to the second electrode E2a of the first light emitting element LEDa. For example, the first connection electrode CEa may be electrically connected to the second electrodes E2a_1 and E2a_2 of the first and second sub-elements LEDa_1 and LEDa_2 through the first sub-pattern CNP1_1 of the first connection pattern CNP1. As a result, the second electrode E2a of the first light emitting element LEDa may be electrically connected to the first pixel driving circuit PCa through the first connection electrode CEa and the first connection pattern CNP1. For example, the second electrodes E2a_1 and E2a_2 of the first and second sub-elements LEDa_1 and LEDa_2 may be electrically connected to the first pixel driving circuit PCa through the first connection electrode CEa and the first connection pattern CNP1.

In an embodiment, a planar profile of an area in which the second electrode E2a of the first light emitting element LEDa contacts the first connection pattern CNP1 may be substantially the same as or similar to a planar profile of edges of the first and second sub-patterns CNP1_1 and CNP1_2 of the first connection pattern CNP1. For example, at least a portion of the second electrode E2a of the first light emitting element LEDa, which contacts the first connection pattern CNP1, and the edges of the first and second sub-patterns CNP1_1 and CNP1_2 of the first connection pattern CNP1 may have a same (or similar) planar profile. For example, a planar profile of an area in which the second electrode E2a_1 of the first sub-element LEDa_1 contacts the first sub-pattern CNP1_1 may be substantially the same as or similar to a planar profile of an edge of the first sub-pattern CNP1_1, and a planar profile of an area in which the second electrode E2a_2 of the second sub-element LEDa_2 contacts the second sub-pattern CNP1_2 may be substantially the same as or similar to a planar profile of an edge of the second sub-pattern CNP1_2. For example, at least a portion of the second electrode E2a_1 of the first sub-element LEDa_1, which contacts the first sub-pattern CNP_1, and the edge of the first sub-pattern CNP1_1 may have a same (or similar) planar profile, and at least a portion of the second electrode E2a_2 of the second sub-element LEDa_2, which contacts the second sub-pattern CNP1_2, and the edge of the second sub-pattern CNP1_2 may have a same (or similar) planar profile.

For example, in case that the first sub-pattern CNP1_1 has a closed ring shape that surrounds the first sub-area EAa_1 as a whole in a plan view, an area in which the second electrode E2a_1 of the first sub-element LEDa_1 contacts the first sub-pattern CNP1_1 may have a closed ring shape in a plan view. In case that the second sub-pattern CNP1_2 has a closed ring shape that surrounds the second sub-area EAa_2 as a whole in a plan view, an area in which the second electrode E2a_2 of the second sub-element LEDa_2 contacts the second sub-pattern CNP1_2 may have a closed ring shape in a plan view.

For example, the second electrode E2a of the first light emitting element LEDa and the first connection pattern CNP1 may be in contact with each other at a position that does not overlap the first light emitting area EAa in a plan view. For example, the second electrode E2a_1 of the first sub-element LEDa_1 and the first sub-pattern CNP1_1 may be in contact with each other at a position that does not overlap the first sub-area EAa_1 in a plan view, and the second electrode E2a_2 of the second sub-element LEDa_2 and the second sub-pattern CNP1_2 may be in contact with each other at a position that does not overlap the second sub-area EAa_2 in a plan view. Accordingly, the second electrode E2a of the first light emitting element LEDa may be electrically connected to the first pixel driving circuit PCa through the first connection pattern CNP1 and the first connection electrode CEa without reducing a light emitting area of the first light emitting area EAa.

In an embodiment, the second connection electrode CEb may overlap the second pixel driving circuit PCb in a plan view. For example, the second connection electrode CEb may not overlap the first pixel driving circuit PCa or the third pixel driving circuit PCc in a plan view. The second connection electrode CEb may include a second circuit connection portion CPb and a second light emitting connection portion CNb.

The second circuit connection portion CPb may be a portion of the second connection electrode CEb that is electrically connected to the second pixel driving circuit PCb. For example, the second circuit connection portion CPb may be a portion of the second connection electrode CEb that is electrically connected to a second transistor (e.g., a second transistor TR2 of FIG. 6) of the second pixel driving circuit PCb. Accordingly, a position of the second circuit connection portion CPb may correspond to a position of the second transistor of the second pixel driving circuit PCb. For example, the position of the second circuit connection portion CPb may correspond to a position of a first contact hole (e.g., a first contact hole CNT1 of FIG. 6) that exposes the second transistor of the second pixel driving circuit PCb and penetrates a fifth insulating layer (e.g., a fifth insulating layer IL5 of FIG. 6).

The second light emitting connection portion CNb may be a portion of the second connection electrode CEb that is electrically connected to the second connection pattern CNP2. For example, the second light emitting connection portion CNb may be a portion of the second connection electrode CEb that is exposed and electrically connected to the second connection pattern CNP2. Accordingly, a position of the second light emitting connection portion CNb may correspond to a position of a second contact hole (e.g., a second contact hole CNT2 of FIG. 6) that exposes the second connection electrode CEb and penetrates a pixel defining layer (e.g., a pixel defining layer PDL of FIG. 6) and a sixth insulating layer (e.g., a sixth insulating layer IL6 of FIG. 6). The second light emitting connection portion CNb may not overlap the second light emitting area EAb in a plan view. For example, the second light emitting connection portion CNb may overlap the separator SPR in a plan view, and may be disposed below the separator SPR.

In an embodiment, the second connection electrode CEb may be spaced apart from the first connection electrode CEa. The first connection electrode CEa and the second connection electrode CEb may be separate electrodes that are distinguished from each other. For example, the first and second connection electrodes CEa and CEb may be electrically insulated from each other.

The second connection pattern CNP2 may be electrically connected to the second connection electrode CEb. For example, the second connection pattern CNP2 may contact (or may be electrically connected to) the second light emitting connection portion CNb of the second connection electrode CEb. The second connection pattern CNP2 may not overlap the second light emitting area EAb in a plan view.

In an embodiment, the second connection pattern CNP2 may be adjacent to (e.g., surround) at least a portion of the second light emitting area EAb in a plan view. For example, the second connection pattern CNP2 may have a closed ring shape that surrounds the second light emitting area EAb as a whole in a plan view. However, embodiments are not limited thereto.

In an embodiment, the second connection pattern CNP2 may be spaced apart from the first connection pattern CNP1. The first connection pattern CNP1 and the second connection pattern CNP2 may be separate patterns that are distinguished from each other. For example, the first and second connection patterns CNP1 and CNP2 may be electrically insulated from each other.

The second electrode E2b of the second light emitting element LEDb may be electrically connected to the second connection pattern CNP2. For example, the second electrode E2b of the second light emitting element LEDb may contact (or may be electrically connected to) the second connection pattern CNP2. Accordingly, the second connection pattern CNP2 may electrically connect the second connection electrode CEb to the second electrode E2b of the second light emitting element LEDb. As a result, the second electrode E2b of the second light emitting element LEDb may be electrically connected to the second pixel driving circuit PCb through the second connection electrode CEb and the second connection pattern CNP2.

In an embodiment, a planar profile of an area in which the second electrode E2b of the second light emitting element LEDb contacts the second connection pattern CNP2 may be substantially the same as or similar to a planar profile of an edge of the second connection pattern CNP2. For example, at least a portion of the second electrode E2b of the second light emitting element LEDb, which contacts the second connection pattern CNP2, and the edge of the second connection pattern CNP2 may have a same (or similar) planar profile. For example, in case that the second connection pattern CNP2 has a closed ring shape that surrounds the second light emitting area EAb as a whole in a plan view, an area in which the second electrode E2b of the second light emitting element LEDb contacts the second connection pattern CNP2 may have a closed ring shape in a plan view. For example, the second electrode E2b and the second connection pattern CNP2 of the second light emitting element LEDb may be in contact with each other at a position that does not overlap the second light emitting area EAb in a plan view. Accordingly, the second electrode E2b of the second light emitting element LEDb may be electrically connected to the second pixel driving circuit PCb through the second connection pattern CNP2 and the second connection electrode CEb without reducing a light emitting area of the second light emitting area EAb.

In an embodiment, the third connection electrode CEc may overlap the third pixel driving circuit PCc in a plan view. For example, the third connection electrode CEc may not overlap the first pixel driving circuit PCa or the second pixel driving circuit PCb in a plan view. The third connection electrode CEc may include a third circuit connection portion CPc and a third light emitting connection portion CNc.

The third circuit connection portion CPc may be a portion of the third connection electrode CEc that is electrically connected to the third pixel driving circuit PCc. For example, the third circuit connection portion CPc may be a portion of the third connection electrode CEc that is electrically connected to a second transistor (e.g., a second transistor TR2 of FIG. 6) of the third pixel driving circuit PCc. Accordingly, a position of the third circuit connection portion CPc may correspond to a position of the second transistor of the third pixel driving circuit PCc. For example, the position of the third circuit connection portion CPc may correspond to a position of a first contact hole (e.g., a first contact hole CNT1 of FIG. 6) that exposes the second transistor of the third pixel driving circuit portion PCc and penetrates a fifth insulating layer (e.g., a fifth insulating layer IL5 of FIG. 6).

The third light emitting connection portion CNc may be a portion of the third connection electrode CEc that is electrically connected to the third connection pattern CNP3. For example, the third light emitting connection portion CNc may be a portion of the third connection electrode CEc that is exposed and electrically connected to the third connection pattern CNP3. Accordingly, a position of the third light emitting connection portion CNc may correspond to a position of a second contact hole (e.g., a second contact hole CNT2 of FIG. 6) that exposes the third connection electrode CEc and penetrates a pixel defining layer (e.g., a pixel defining layer PDL of FIG. 6) and a sixth insulating layer (e.g., a sixth insulating layer IL6 of FIG. 6). The third light emitting connection portion CNc may not overlap the third light emitting area EAc in a plan view. For example, the third light emitting connection portion CNc may overlap the separator SPR in a plan view, and may be disposed below the separator SPR.

In an embodiment, the third connection electrode CEc may be spaced apart from the first connection electrode CEa and the second connection electrode CEb. The first connection electrode CEa, the second connection electrode CEb, and the third connection electrode CEc may be separate electrodes that are distinguished from each other. For example, the first, second, and third connection electrodes CEa, CEb, and CEc may be electrically insulated from each other.

The third connection pattern CNP3 may be electrically connected to the third connection electrode CEc. For example, the third connection pattern CNP3 may contact (or may be electrically connected to) the third light emitting connection portion CNc of the third connection electrode CEc. The third connection pattern CNP3 may not overlap the third light emitting area EAc in a plan view.

In an embodiment, the third connection pattern CNP3 may be adjacent to (e.g., surround) at least a portion of the third light emitting area EAc in a plan view. For example, the third connection pattern CNP3 may have a closed ring shape that surrounds the third light emitting area EAc as a whole in a plan view. However, embodiments are not limited thereto.

In an embodiment, the third connection pattern CNP3 may be spaced apart from the first connection pattern CNP1 and the second connection pattern CNP2. The first connection pattern CNP1, the second connection pattern CNP2, and the third connection pattern CNP3 may be separate patterns that are distinguished from each other. For example, the first, second, and third connection patterns CNP1, CNP2, and CNP3 may be electrically insulated from each other.

The second electrode E2c of the third light emitting element LEDc may be electrically connected to the third connection pattern CNP3. For example, the second electrode E2c of the third light emitting element LEDc may contact (or may be electrically connected to) the third connection pattern CNP3. Accordingly, the third connection pattern CNP3 may electrically connect the third connection electrode CEc to the second electrode E2c of the third light emitting element LEDc. As a result, the second electrode E2c of the third light emitting element LEDc may be electrically connected to the third pixel driving circuit PCc through the third connection electrode CEc and the third connection pattern CNP3.

In an embodiment, a planar profile of an area in which the second electrode E2c of the third light emitting element LEDc contacts the third connection pattern CNP3 may be substantially the same as or similar to a planar profile of an edge of the third connection pattern CNP3. For example, at least a portion of the second electrode E2c of the third light emitting element LEDc, which contacts the third connection pattern CNP3, and the edge of the third connection pattern CNP3 may have a same (or similar) planar profile. For example, in case that the third connection pattern CNP3 has a closed ring shape that surrounds the third light emitting area EAc as a whole in a plan view, an area in which the second electrode E2c of the third light emitting element LEDc contacts the third connection pattern CNP3 may have a closed ring shape in a plan view. For example, the second electrode E2c of the third light emitting element LEDc and the third connection pattern CNP3 may be in contact with each other at a position that does not overlap the third light emitting area EAc in a plan view. Accordingly, the second electrode E2c of the third light emitting element LEDc may be electrically connected to the third pixel driving circuit PCc through the third connection pattern CNP3 and the third connection electrode CEc without reducing a light emitting area of the third light emitting area EAc.

According to embodiments, the second electrodes E2a, E2b, and E2c may contact (or may be electrically connected to) the connection patterns CNP1, CNP2, and CNP3 at positions that do not overlap the light emitting areas EAa, EAb, and EAc, respectively, in a plan view. Accordingly, the second electrodes E2a, E2b, and E2c may contact (or may be electrically connected to) the connection patterns CNP1, CNP2, and CNP3 without reducing the light emitting areas.

According to embodiments, the second electrodes E2a, E2b, and E2c may be electrically connected to the pixel driving circuits PCa, PCb, and PCc through the connection electrodes CEa, CEb, and CEc and the connection patterns CNP1, CNP2, and CNP3, respectively. Accordingly, constraints on the position, shape, and size of the light emitting areas EAa, EAb, and EAc in the design of the pixel driving circuits PCa, PCb, and PCc may be reduced. For example, the light emitting areas EAa, EAb, and EAc may have various positions, shapes, and sizes, and the design margin of the pixel driving circuits PCa, PCb, and PCc may be improved. For example, even when at least a portion of the circuit connection portions CPa, CPb, and CPc overlap the light emitting areas EAa, EAb, and EAc in a plan view, the second electrodes E2a, E2b, and E2c may be readily connected to the pixel driving circuits PCa, PCb, and PCc through the connection electrodes CEa, CEb, and CEc and the connection patterns CNP1, CNP2, and CNP3. Accordingly, the shape, arrangement, or the like of the pixel driving circuits PCa, PCb, and PCc may be designed independently of the position, shape, and size of the light emitting areas EAa, EAb, and EAc. For example, the pixel driving circuits PCa, PCb, and PCc may have various shapes, arrangements, or the like without limitation of the position, shape, or size of the light emitting areas EAa, EAb, and EAc. Accordingly, the degree of freedom in the design of the pixel driving circuits PCa, PCb, and PCc may be improved.

According to embodiments, the arrangement of the first, second, and third pixel driving circuits PCa, PCb, and PCc may be designed such that the first, second, and third connection electrodes CEa, CEb, and CEc electrically connecting the second electrode layer E2 and the first, second, and third pixel driving circuit portions PCa, PCb, and PCc, respectively, are efficiently arranged. For example, the first, second, and third pixel driving circuits PCa, PCb, and PCc may have an optimized arrangement, and the first, second, and third connection electrodes CEa, CEb, and CEc, which electrically connect the second electrode layer E2 and the first, second, and third pixel driving circuit portions PCa, PCb, and PCc, respectively, may have an efficient arrangement. The arrangement of the first, second, and third pixel driving circuits PCa, PCb, and PCc may be designed such that lengths (or areas) of the first, second, and third connection electrodes CEa, CEb, and CEc may be minimized. For example, the first, second, and third pixel driving circuits PCa, PCb, and PCc may have an optimized arrangement, and the lengths (or the areas) of the first, second, and third connection electrodes CEa, CEb, and CEc may be decreased. In an embodiment, as a pixel driving circuit (e.g., the first pixel driving circuit PCa) electrically connected to a light emitting element including sub-elements (e.g., the first light emitting element LEDa) is disposed between pixel driving circuits (e.g., the second and third pixel driving circuits PCb and PCc) respectively connected to other light emitting elements (e.g., the second and third light emitting elements LEDb and LEDc) in a plan view, the lengths of the first, second, and third connection electrodes CEa, CEb, and CEc may be reduced.

In an embodiment, the first, second, and third pixel driving circuits PCa, PCb, and PCc may be designed to be the same regardless of the position, shape, size, or the like of the light emitting areas EAa, EAb, and EAc. For example, the first, second, and third pixel driving circuits PCa, PCb, and PCc may have a same design, and the light emitting areas EAa, EAb, and EAc may have various positions, shapes, sizes, or the like. As described above, the position of the first circuit connection portion CPa may correspond to the position of the second transistor of the first pixel driving circuit PCa, the position of the second circuit connection portion CPb may correspond to the position of the second transistor of the second pixel driving circuit PCb, and the position of the third circuit connection portion CPc may correspond to the position of the second transistor of the third pixel driving circuit PCc. Accordingly, in case that the first, second, and third pixel driving circuits PCa, PCb, and PCc are formed to have substantially the same size and be disposed along the first direction DR1, the position of the second circuit connection portion CPb, the position of the first circuit connection portion CPa, and the position of the third circuit connection portion CPc may be sequentially disposed along the first direction DR1.

As illustrated in FIG. 3, the shape or arrangement of each of the first, second, and third connection electrodes CEa, CEb, and CEc and the arrangement relationship between the first, second, and third connection electrodes CEa, CEb, and CEc may be the same for each first unit light emitting area UEA1. The shape or arrangement of each of the first, second, and third connection electrodes CEa, CEb, and CEc and the arrangement relationship between the first, second, and third connection electrodes CEa, CEb, and CEc may be the same for each second unit light emitting area UEA2. For example, the first, second, and third connection electrodes CEa, CEb, and CEc may have a same arrangement relationship (or a same shape) in each first unit light emitting area UEA1, and the first, second, and third connection electrodes CEa, CEb, and CEc may have a same arrangement relationship (or a same shape) in each second unit light emitting area UEA2.

The shape or arrangement of each of the first, second, and third connection patterns CNP1, CNP2, and CNP3 and the arrangement relationship between the first, second, and third connection patterns CNP1, CNP2, and CNP3 may be the same for each first unit light emitting area UEA1. The shape or arrangement of each of the first, second, and third connection patterns CNP1, CNP2, and CNP3 and the arrangement relationship between the first, second, and third connection patterns CNP1, CNP2, and CNP3 may be the same for each second unit light emitting area UEA2. For example, the first, second, and third connection patterns CNP1, CNP2, and CNP3 may have a same arrangement relationship (or a same shape) in each first unit light emitting area UEA1, and the first, second, and third connection patterns CNP1, CNP2, and CNP3 may have a same arrangement relationship (or a same shape) in each second unit light emitting area UEA2.

As described above, the display device 10 may include the separator SPR. The separator SPR may be disposed on the pixel defining layer PDL (e.g., refer to FIG. 6) and the first, second, and third connection patterns CNP1, CNP2, and CNP3. In an embodiment, the separator SPR may include an organic insulating material. For example, the separator SPR may include a photosensitive resin (e.g., a photoresist), but embodiments are not limited thereto.

The separator SPR may overlap the first, second, and third connection patterns CNP1, CNP2, and CNP3 in a plan view. For example, the separator SPR may cover portions of the first, second, and third connection patterns CNP1, CNP2, and CNP3 and portions (e.g., portions of the pixel defining layer PDL) between adjacent connection patterns. For example, the separator SPR may cover a portion of each of the first and second sub-patterns CNP1_1 and CNP1_2, a portion of each of the second and third connection patterns CNP2 and CNP3, the third sub-pattern CNP1_3, and portions (e.g., portions of the pixel defining layer PDL) between adjacent connection patterns. At least a portion of the separator SPR may extend along edges of the first and second sub-patterns CNP1_1 and CNP1_2 and the second and third connection patterns CNP2 and CNP3 in a plan view. Accordingly, an area in which the second electrode layer E2 contacts the first, second, and third connection patterns CNP1, CNP2, and CNP3 may be adjacent to or overlap an area in which the separator SPR is disposed in a plan view.

The separator SPR may separate (or disconnect) the second electrode layer E2 into the second electrodes E2a_1, E2a_2, E2b, and E2c. For example, the second electrode E2a_1 of the first sub-element LEDa_1 of the first light emitting element LEDa, the second electrode E2a_2 of the second sub-element LEDa_2 of the first light emitting element LEDa, the second electrode E2b of the second light emitting element LEDb, and the second electrode E2c of the third light emitting element LEDc may be electrically insulated from each other by the separator SPR.

The separator SPR may define a first open area OA1, a second open area OA2, a third open area OA3, and a fourth open area OA4 corresponding to the second electrodes E2a_1, E2a_2, E2b, and E2c, respectively. For example, the second electrodes E2a_1, E2a_2, E2b, and E2c may be disposed in the first, second, third, and fourth open areas OA1, OA2, OA3, and OA4, respectively. For example, the separator SPR may have a mesh structure that surrounds the second electrodes E2a_1, E2a_2, E2b, and E2c in a plan view. For example, the second electrode E2a_1 of the first sub-element LEDa_1 of the first light emitting element LEDa may be disposed in the first open area OA1 of the separator SPR, the second electrode E2a_2 of the second sub-element LEDa_2 of the first light emitting element LEDa may be disposed in the second open area OA2 of the separator SPR, the second electrode E2b of the second light emitting element LEDb may be disposed in the third open area OA3 of the separator SPR, and the second electrode E2c of the third light emitting element LEDc may be disposed in the fourth open area OA4 of the separator SPR.

In an embodiment, a planar shape of the first, second, third, and fourth open areas OA1, OA2, OA3, and OA4 of the separator SPR may be substantially the same as a planar shape of the second electrode layer E2. For example, the first, second, third, and fourth open areas OA1, OA2, OA3, and OA4 of the separator SPR and the second electrode layer E2 may have a same planar shape. For example, the first open area OA1 and the second electrode E2a_1 of the first sub-element LEDa_1 of the first light emitting element LEDa may have a same planar shape, the second open area OA2 and the second electrode E2a_2 of the second sub-element LEDa_2 of the first light emitting element LEDa may have a same planar shape, the third open area OA3 and the second electrode E2b of the second light emitting element LEDb may have a same planar shape, and the fourth open area OA4 and the second electrode E2c of the third light emitting element LEDc may have a same planar shape.

In an embodiment, the first, second, third, and fourth open areas OA1, OA2, OA3, and OA4 of the separator SPR may correspond to the first, second, and third connection patterns CNP1 (e.g., the first sub-pattern CNP1_1 and the second sub-pattern CNP1_2), CNP2, and CNP3. For example, the first and second sub-patterns CNP1_1 and CNP1_2 of the first connection pattern CNP1, the second connection pattern CNP2, and the third connection pattern CNP3 may be disposed in the first, second, third, and fourth open areas OA1, OA2, OA3, and OA4, respectively. For example, the first sub-pattern CNP1_1 of the first connection pattern CNP1 may overlap the first open area OA1 in a plan view, the second sub-pattern CNP1_2 of the first connection pattern CNP1 may overlap the second open area OA2 in a plan view, the second connection pattern CNP2 may overlap the third open area OA3 in a plan view, and the third connection pattern CNP3 may overlap the fourth open area OA4 in a plan view. Hereinafter, a cross-sectional structure of the display device 10 will be described in more detail with reference to FIGS. 5 and 6. Although FIG. 5 illustrates the second light emitting area EAb and FIG. 6 illustrates the third light emitting area EAc, the following description of the cross-sectional structure of the display device 10 may be substantially equally applied to all light emitting areas.

Referring to FIGS. 5 and 6, the display device 10 may include a substrate SUB, a first lower conductive layer BML1, a second lower conductive layer BML2, a first transistor TR1, a second transistor TR2, a first capacitor CAP1, a second capacitor CAP2, the third connection electrode CEc, a first insulating layer IL1, a second insulating layer IL2, a third insulating layer IL3, a fourth insulating layer IL4, a fifth insulating layer IL5, a sixth insulating layer IL6, a pixel defining layer PDL, the first connection pattern CNP1 (e.g., refer to FIG. 4), the second connection pattern CNP2, the third connection pattern CNP3, the second light emitting element LEDb, the third light emitting element LEDc, the separator SPR, a first dummy layer DP1, a second dummy layer DP2, and an encapsulation layer ENC.

The first transistor TR1 may include a first active pattern AP1, a first gate electrode GE1, a first contact electrode SE1, and a second contact electrode DE1. The second transistor TR2 may include a second active pattern AP2, a second gate electrode GE2, a third contact electrode SE2, and a fourth contact electrode DE2. The first capacitor CAP1 may include a first capacitor electrode CPE1 and a second capacitor electrode CPE2. The second capacitor CAP2 may include the first capacitor electrode CPE1 and a third capacitor electrode CPE3. The second light emitting element LEDb may include a first electrode E1, an intermediate layer ML, and the second electrode E2b. The third light emitting element LEDc may include a first electrode E1, an intermediate layer ML, and the second electrode E2c.

As described above, the first transistor TR1, the second transistor TR2, the first capacitor CAP1, and the second capacitor CAP2 may be components included in each of the first, second, and third pixel driving circuits PCa, PCb, and PCc.

The substrate SUB may be (or serve as) a base of the display device 10. In an embodiment, examples of materials that may be used as the substrate SUB may include glass, quartz, silicon, polymer, or the like. These may be used alone or in combination with each other. The substrate SUB may have a single-layer structure or a multi-layer structure in which layers including different materials are stacked each other.

The first lower conductive layer BML1, the second lower conductive layer BML2, and the third capacitor electrode CPE3 may be disposed on the substrate SUB. The first lower conductive layer BML1, the second lower conductive layer BML2, and the third capacitor electrode CPE3 may include a conductive material such as a metal, an alloy, a conductive metal oxide, a conductive metal nitride, a transparent conductive oxide, or the like. These may be used alone or in combination with each other.

The first insulating layer IL1 may be disposed on the substrate SUB, and may cover the first lower conductive layer BML1, the second lower conductive layer BML2, and the third capacitor electrode CPE3. The first insulating layer IL1 may prevent metal atoms or impurities from diffusing from the substrate SUB to the first active pattern AP1 or the second active pattern AP2. The first insulating layer IL1 may include an insulating material. Examples of the insulating material that may be used as the first insulating layer IL1 may include silicon oxide, silicon nitride, silicon oxynitride, or the like. These may be used alone or in combination with each other.

The first active pattern AP1 and the second active pattern AP2 may be disposed on the first insulating layer IL1. In an embodiment, the first active pattern AP1 may overlap the first lower conductive layer BML1 in a plan view, and the second active pattern AP2 may overlap the second lower conductive layer BML2 in a plan view. The first and second active patterns AP1 and AP2 may include an oxide semiconductor material, a silicon semiconductor material, an organic semiconductor material, or the like. These may be used alone or in combination with each other. The first active pattern AP1 may include a first contact area S1, a second contact area D1, and a first channel area CH1 between the first contact area S1 and the second contact area D1, and the second active pattern AP2 may include a third contact area S2, a fourth contact area D2, and a second channel area CH2 between the third contact area S2 and the fourth contact area D2. The first contact area S1 and the second contact area D1 may have higher conductivity than the first channel area CH1, and the third contact area S2 and the fourth contact area D2 may have higher conductivity than the second channel area CH2.

In an embodiment, the first and second active patterns AP1 and AP2 may include an oxide semiconductor material. Examples of the oxide semiconductor material that may be used as the first and second active patterns AP1 and AP2 may include indium gallium zinc oxide, zinc tin oxide, indium tin zinc oxide, or the like. These may be used alone or in combination with each other. However, embodiments are not limited thereto, and in an embodiment, the first and second active patterns AP1 and AP2 may include different materials. For example, any one of the first and second active patterns AP1 and AP2 may include an oxide semiconductor material, and another may include a silicon semiconductor material.

Although FIGS. 5 and 6 illustrate the first active pattern AP1 and the second active pattern AP2 disposed on a same layer, embodiments are not limited thereto, and the first active pattern AP1 and the second active pattern AP2 may be disposed on different layers.

The second insulating layer IL2 may be disposed on the first insulating layer IL1, and may cover the first active pattern AP1 and the second active pattern AP2. The second insulating layer ILD2 may include an insulating material. Examples of the insulating material that may be used as the second insulating layer IL2 may include silicon oxide, silicon nitride, silicon oxynitride, or the like. These may be used alone or in combination with each other.

The first gate electrode GE1, the second gate electrode GE2, and the first capacitor electrode CPE1 may be disposed on the second insulating layer IL2. The first gate electrode GE1 may overlap the first channel area CH1 of the first active pattern AP1 in a plan view, and the second gate electrode GE2 may overlap the second channel area CH2 of the second active pattern AP2 in a plan view. The first capacitor electrode CPE1 may overlap the third capacitor electrode CPE3 in a plan view, and the first capacitor electrode CPE1 and the third capacitor electrode CPE3 may form the second capacitor CAP2. The first gate electrode GE1, the second gate electrode GE2, and the first capacitor electrode CPE1 may include a conductive material such as a metal, an alloy, a conductive metal oxide, a conductive metal nitride, a transparent conductive oxide, or the like. These may be used alone or in combination with each other. Although not shown, in an embodiment, the first gate electrode GE1 may contact (or may be electrically connected to) the first lower conductive layer BML1. Although not shown, in an embodiment, the second gate electrode GE2 may contact (or may be electrically connected to) the second lower conductive layer BML2.

Although FIGS. 5 and 6 illustrate the first gate electrode GE1, the second gate electrode GE2, and the first capacitor electrode CPE1 disposed on a same layer, embodiments are not limited thereto, and the first gate electrode GE1, the second gate electrode GE2, and the first capacitor electrode CPE1 may be disposed on different layers.

The third insulating layer IL3 may be disposed on the second insulating layer IL2, and may cover the first gate electrode GE1, the second gate electrode GE2, and the first capacitor electrode CPE1. The third insulating layer IL3 may include an insulating material. Examples of the insulating material that may be used as the third insulating layer IL3 may include silicon oxide, silicon nitride, silicon oxynitride, or the like. These may be used alone or in combination with each other.

The second capacitor electrode CPE2 may be disposed on the third insulating layer IL3. The second capacitor electrode CPE2 may overlap the first capacitor electrode CPE1 in a plan view, and the first capacitor electrode CPE1 and the second capacitor electrode CPE2 may form the first capacitor CAP1. The second capacitor electrode CPE2 may include a conductive material such as a metal, an alloy, a conductive metal oxide, a conductive metal nitride, a transparent conductive oxide, or the like. These may be used alone or in combination with each other.

The fourth insulating layer IL4 may be disposed on the third insulating layer IL3, and may cover the second capacitor electrode CPE2. The fourth insulating layer IL4 may include an insulating material. Examples of the insulating material that may be used as the fourth insulating layer IL4 may include silicon oxide, silicon nitride, silicon oxynitride, or the like. These may be used alone or in combination with each other.

The first, second, third, and fourth contact electrodes SE1, DE1, SE2, and DE2 may be disposed on the fourth insulating layer IL4. The first contact electrode SE1 may contact the first contact area S1 of the first active pattern AP1, and the second contact electrode DE1 may contact the second contact area D1 of the first active pattern AP1. The third contact electrode SE2 may contact the third contact area S2 of the second active pattern AP2, and the fourth contact electrode DE2 may contact the fourth contact area D2 of the second active pattern AP2. For example, the third contact electrode SE2 may be electrically connected to the second active pattern AP2 in the third contact area S2, and the fourth contact electrode DE2 may be electrically connected to the second active pattern AP2 in the fourth contact area D2. The first, second, third, and fourth contact electrodes SE1, DE1, SE2, and DE2 may include a conductive material such as a metal, an alloy, a conductive metal oxide, a conductive metal nitride, a transparent conductive oxide, or the like. These may be used alone or in combination with each other.

In an embodiment, the first contact electrode SE1 may (or may be electrically connected to) contact the first lower conductive layer BML1, and the third contact electrode SE2 may contact (or may be electrically connected to) the second lower conductive layer BML2. However, embodiments are not limited thereto. For example, in case that the first gate electrode GE1 contacts the first lower conductive layer BML1, the first contact electrode SE1 may not contact the first lower conductive layer BML1, and in case that the second gate electrode GE2 contacts the second lower conductive layer BML2, the third contact electrode SE2 may not contact the second lower conductive layer BML2.

The fifth insulating layer IL5 may be disposed on the fourth insulating layer IL4, and may cover the first, second, third, and fourth contact electrodes SE1, DE1, SE2, and DE2. The fifth insulating layer IL5 may include an insulating material. For example, the fifth insulating layer IL5 may include an organic insulating material. Examples of the organic insulating material that may be used as the fifth insulating layer IL5 may include a photoresist, a polyacrylic resin, a polyimide resin, a polyamide resin, a siloxane resin, an acrylic resin, an epoxy resin, or the like. These may be used alone or in combination with each other.

The third connection electrode CEc may be disposed on the fifth insulating layer IL5. As described above, the third connection electrode CEc may be electrically connected to the second transistor TR2. For example, the third connection electrode CEc may contact (or may be electrically connected to) the second transistor TR2 through the first contact hole CNT1 penetrating the fifth insulating layer IL5. Accordingly, a position of the third circuit connection portion CPc may correspond to a position of the first contact hole CNT1. The third connection electrode CEc may include a conductive material such as a metal, an alloy, a conductive metal oxide, a conductive metal nitride, a transparent conductive oxide, or the like. These may be used alone or in combination with each other. In an embodiment, the third connection electrode CEc may have a single-layer structure or a multi-layer structure in which conductive layers are stacked each other.

As described above, the second transistor TR2 may be a transistor electrically connected to a light emitting element through a connection electrode and a connection pattern. For example, in case that the third pixel driving circuit PCc is the pixel driving circuit PC of FIG. 2A, the second transistor TR2 may be the first transistor T1 of FIG. 2A. For another example, in case that the third pixel driving circuit PCc is the pixel driving circuit PC′ of FIG. 2B, the second transistor TR2 may be the fifth transistor T5 of FIG. 2B.

The sixth insulating layer IL6 may be disposed on the fifth insulating layer IL5, and may cover the third connection electrode CEc. The sixth insulating layer IL6 may include an insulating material. For example, the sixth insulating layer IL6 may include an organic insulating material. Examples of the organic insulating material that may be used as the sixth insulating layer IL6 may include a photoresist, a polyacrylic resin, a polyimide resin, a polyamide resin, a siloxane resin, an acrylic resin, an epoxy resin, or the like. These may be used alone or in combination with each other.

The first electrode E1 may be disposed on the sixth insulating layer IL6. The first electrode E1 may include a conductive material such as a metal, an alloy, a conductive metal oxide, a conductive metal nitride, a transparent conductive oxide, or the like. These may be used alone or in combination with each other.

The pixel defining layer PDL may be disposed on the sixth insulating layer IL6 and the first electrode E1. The pixel defining layer PDL may include an insulating material. The pixel defining layer PDL may define pixel openings each exposing at least a portion of the first electrode E1. The second and third light emitting areas EAb and EAc may be defined by the pixel openings.

The first, second, and third connection patterns CNP1, CNP2, and CNP3 may be disposed on the pixel defining layer PDL. The first, second, and third connection patterns CNP1, CNP2, and CNP3 may be spaced apart from each other. As described above, the third connection pattern CNP3 may be electrically connected to the third connection electrode CEc. For example, the third connection pattern CNP3 may contact (or may be electrically connected to) the third connection electrode CEc through a second contact hole CNT2 penetrating the sixth insulating layer IL6 and the pixel defining layer PDL. Accordingly, a position of the third light emitting connection portion CNc may correspond to a position of the second contact hole CNT2. In an embodiment, the third connection pattern CNP3 may include a transparent conductive oxide. However, embodiments are not limited thereto, and in an embodiment, the third connection pattern CNP3 may include a conductive material such as a metal, an alloy, a conductive metal oxide, a conductive metal nitride, or the like. These may be used alone or in combination with each other. In an embodiment, the third connection pattern CNP3 may have a single-layer structure or a multi-layer structure in which conductive layers are stacked each other.

The separator SPR may be disposed on the pixel defining layer PDL and the first, second, and third connection patterns CNP1, CNP2, and CNP3. The separator SPR may overlap the first, second, and third connection patterns CNP1, CNP2, and CNP3 in a plan view. For example, the separator SPR may cover a portion of the second sub-pattern CNP1_2, a portion of each of the second and third connection patterns CNP2 and CNP3, and the third sub-pattern CNP1_3.

The separator SPR may have a shape in which an upper width is greater than a lower width. For example, a side surface of the separator SPR electrically connecting an upper surface of the separator SPR and a lower surface of the separator SPR may have a reverse-tapered inclined surface. A cross-sectional shape of at least a portion of the separator SPR may be a reverse trapezoid.

In an embodiment, as illustrated in FIGS. 5 and 6, the side surface of the separator SPR may have reverse-tapered inclined surfaces. For example, the separator SPR may have a double reverse-tapered structure. Accordingly, the second electrode layer E2 may be more readily separated (or disconnected) by the separator SPR.

The intermediate layer ML may be disposed on the first electrode E1, the pixel defining layer PDL, and the first, second, and third connection patterns CNP1, CNP2, and CNP3. A portion of the intermediate layer ML may be disposed in the pixel openings of the pixel defining layer PDL. In an embodiment, the intermediate layer ML may include a first functional layer including an organic material, a light emitting layer disposed on the first functional layer and including a light emitting material, and a second functional layer disposed on the light emitting layer and including an organic material. For example, the first functional layer may include a hole injection layer, a hole transport layer, or the like, and the second functional layer may include an electron transport layer, an electron injection layer, or the like. A shadow area in which it is difficult to deposit the intermediate layer ML may exist around the separator SPR having the reverse-tapered inclined surface. For example, the intermediate layer ML may not exist in the shadow area, and the shadow area may be disposed adjacent to the reverse-tapered inclined surface of the separator SPR. Accordingly, the intermediate layer ML may have a structure that is separated (or disconnected) by the separator SPR in the shadow area or around the shadow area. For example, each of the first and second functional layers included in the intermediate layer ML may have a structure that is separated (or disconnected) by the separator SPR. Since the intermediate layer ML has a structure that is separated (or disconnected), the intermediate layer ML may not cover the first, second, and third connection patterns CNP1, CNP2, and CNP3 as a whole. For example, the intermediate layer ML may expose a portion of each of the first, second, and third connection patterns CNP1, CNP2, and CNP3 at a position adjacent to or overlapping the separator SPR in a plan view. Accordingly, the second electrode E2a of the first light emitting element LEDa may contact (or may be electrically connected to) the first connection pattern CNP1, the second electrode E2b of the second light emitting element LEDb may contact (or may be electrically connected to) the second connection pattern CNP2, and the second electrode E2c of the third light emitting element LEDc may contact (or may be electrically connected to) the third connection pattern CNP3.

The first dummy layer DP1 may be disposed on the separator SPR. The first dummy layer DP1 may be formed as the intermediate layer ML has a structure that is separated (or disconnected) by the separator SPR. For example, the first dummy layer DP1 and the intermediate layer ML may be formed in a same process and include a same material. In an embodiment, the first dummy layer DP1 may be omitted.

The second electrode layer E2 may be disposed on the intermediate layer ML. The second electrode layer E2 may include a conductive material such as a metal, an alloy, a conductive metal oxide, a conductive metal nitride, a transparent conductive oxide, or the like. These may be used alone or in combination with each other. In an embodiment, the second electrode layer E2 may have a single-layer structure. However, embodiments are not limited thereto, and in an embodiment, the second electrode layer E2 may have a multi-layer structure in which conductive layers are stacked each other. For example, the second electrode layer E2 may have a two-layer structure in which a first layer including a metal material and a second layer disposed on the first layer and including a transparent conductive oxide are stacked each other.

A shadow area in which it is difficult to deposit the second electrode layer E2 may exist around the separator SPR having the reverse-tapered inclined surface. For example, the second electrode layer E2 may not exist in the shadow area. Accordingly, the second electrode layer E2 may have a structure that is separated (or disconnected) by the separator SPR in the shadow area or around the shadow area. For example, as illustrated in FIG. 4, the second electrode layer E2 may be separated (or disconnected) into the second electrode E2a_1 of the first sub-element LEDa_1 of the first light emitting element LEDa disposed in the first open area OA1 of the separator SPR, the second electrode E2a_2 of the second sub-element LEDa_2 of the first light emitting element LEDa disposed in the second open area OA2 of the separator SPR, the second electrode E2b of the second light emitting element LEDb disposed in the third open area OA3 of the separator SPR, and the second electrode E2c of the third light emitting element LEDc disposed in the fourth open area OA4 of the separator SPR. For example, the second electrodes E2a_1, E2a_2, E2b, and E2c may be electrically insulated from each other.

The second electrodes E2a, E2b, and E2c of the first, second, and third light emitting elements LEDa, LEDb, and LEDc may be electrically connected to the first, second, and third connection patterns CNP1, CNP2, and CNP3, respectively. For example, as illustrated in FIGS. 5 and 6, the second electrode E2a_2 of the second sub-element LEDa_2 may contact (or may be electrically connected to) the second sub-pattern CNP1_2 at a position adjacent to or overlapping the separator SPR in a plan view, the second electrode E2b of the second light emitting element LEDb may contact (or may be electrically connected to) the second connection pattern CNP2 at a position adjacent to or overlapping the separator SPR in a plan view, and the second electrode E2c of the third light emitting element LEDc may contact (or may be electrically connected to) the third connection pattern CNP3 at a position adjacent to or overlapping the separator SPR in a plan view.

For example, in case that a deposition angle of a deposition process for forming the second electrode layer E2 is greater than a deposition angle of a deposition process for forming the intermediate layer ML, the second electrode layer E2 may cover a side portion of the separated (or disconnected) intermediate layer ML and contact the first, second, and third connection patterns CNP1, CNP2, and CNP3. As a result, the second electrode layer E2 may be electrically connected to the second transistor TR2 through the first, second, and third connection patterns CNP1, CNP2, and CNP3. For example, the second electrode E2c of the third light emitting element LEDc may be electrically connected to the second transistor TR2 through the third connection electrode CEc and the third connection pattern CNP3.

The second dummy layer DP2 may be disposed on the separator SPR. The second dummy layer DP2 may be disposed on the first dummy layer DP1. The second dummy layer DP2 may be formed as the second electrode layer E2 has a structure that is separated (or disconnected) by the separator SPR. For example, the second dummy layer DP2 and the second electrode layer E2 may be formed in a same process and include a same material. In an embodiment, the second dummy layer DP2 may be omitted.

The encapsulation layer ENC may be disposed on the second electrode layer E2. The encapsulation layer ENC may cover the second electrode layer E2, the first, second, and third connection patterns CNP1, CNP2, and CNP3, the separator SPR, and the first and second dummy layers DP1 and DP2 as a whole. For example, the encapsulation layer ENC may include a first inorganic encapsulation layer IEL1 including an inorganic insulating material, an organic encapsulation layer OEL disposed on the first inorganic encapsulation layer IEL1 and including an organic insulating material, and a second inorganic encapsulation layer IEL2 disposed on the organic encapsulation layer OEL and including an inorganic insulating material.

Although not shown, in an embodiment, a touch sensing layer may be further disposed on the encapsulation layer ENC. For example, the touch sensing layer may include touch electrode arrays for sensing a user's handling in a capacitive manner, a touch pad portion, and touch lines electrically connecting the touch pad portion to the touch electrode arrays. However, embodiments are not limited thereto, and in an embodiment, the touch sensing layer may be omitted.

According to embodiments, the display device 10 may include the connection electrodes CEa, CEb, and CEc, the connection patterns CNP1, CNP2, and CNP3, and the separator SPR. Accordingly, the second electrode layer E2 (e.g., a cathode) disposed on the first electrode E1 (e.g., an anode) may be readily connected to the pixel driving circuits PCa, PCb, and PCc. For example, the second electrode layer E2 disposed on the first electrode E1 may be electrically connected to a drain of a driving transistor (e.g., the first transistor T1 of FIGS. 2A and 2B) of each of the pixel driving circuits PCa, PCb, and PCc through the connection electrodes CEa, CEb, and CEc and the connection patterns CNP1, CNP2, and CNP3. Accordingly, even when the light emitting element deteriorates, the gate-source voltage (Vgs) of the driving transistor may not be changed, and thus the range of change in the driving current due to the deterioration of the light emitting element may be reduced. Accordingly, the after-image defect of the display device 10 due to an increase in time of use may be reduced, and the lifespan of the display device 10 may be improved.

According to embodiments, the display device 10 may include the first light emitting element LEDa including the first and second sub-elements LEDa_1 and LEDa_2 spaced apart from each other. The first pixel driving circuit PCa electrically connected to the first light emitting element LEDa may be disposed between the second and third pixel driving circuits PCb and PCc respectively connected to the second and third light emitting elements LEDb and LEDc in a plan view. Accordingly, the first, second, and third connection electrodes CEa, CEb, and CEc electrically connecting the second electrode layer E2 to the first, second, and third pixel driving circuits PCa, PCb, and PCc, respectively, may reduce an area they (e.g., the first, second, and third connection electrodes CEa, CEb, and CEc) occupy. Accordingly, parasitic capacitance by the first, second, and third connection electrodes CEa, CEb, and CEc may be reduced, and display quality of the display device 10 may be improved.

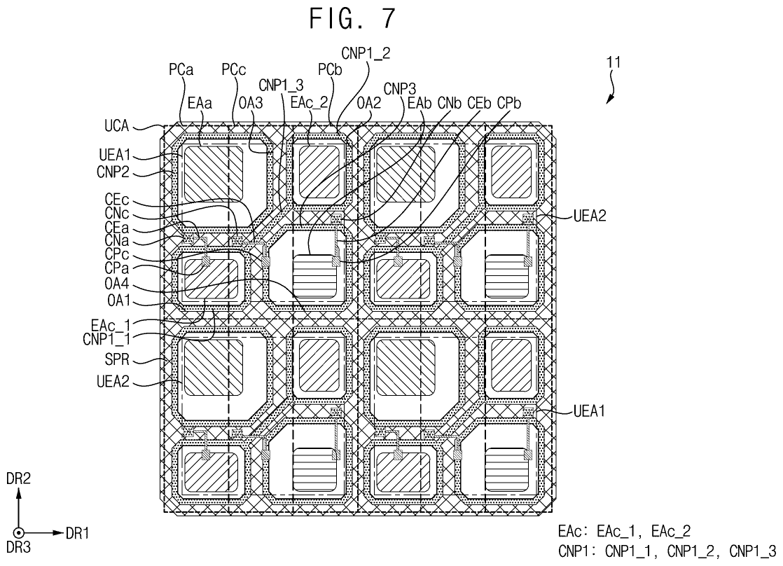

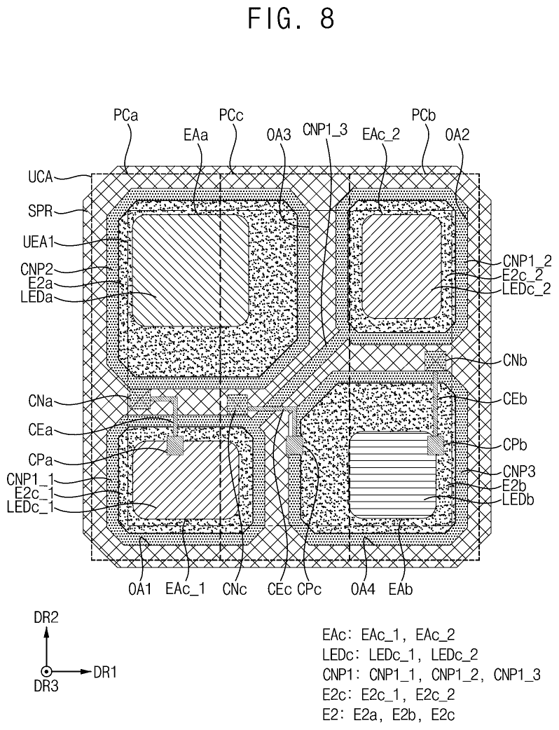

FIG. 7 is a schematic plan view illustrating a display device according to an embodiment of the disclosure. FIG. 8 is a schematic enlarged view illustrating a portion of FIG. 7.

For example, FIG. 7 may correspond to the plan view of FIG. 3, and FIG. 8 may correspond to the enlarged view of FIG. 4. For example, FIG. 7 may be a plan view schematically illustrating a portion of a display device 11, and FIG. 8 may be an enlarged view illustrating a first unit light emitting area UEA1 among unit light emitting areas UEA1 and UEA2 of FIG. 7.

Hereinafter, detailed description of the same or similar constituent elements with the display device 10 described with reference to FIGS. 1A to 6 is omitted or simplified.

Referring to FIGS. 7 and 8, the display device 11 may include a first pixel driving circuit PCa, a second pixel driving circuit PCb, a third pixel driving circuit PCc, a first light emitting element LEDa, a second light emitting element LEDb, a third light emitting element LEDc, a first connection electrode CEa, a second connection electrode CEb, a third connection electrode CEc, a first connection pattern CNP1, a second connection pattern CNP2, a third connection pattern CNP3, and a separator SPR.

Each of the first, second, and third pixel driving circuits PCa, PCb, and PCc may include at least one transistor and at least one capacitor.

At least one of the first, second, and third light emitting elements LEDa, LEDb, and LEDc may include sub-elements spaced apart from each other. In an embodiment, the third light emitting element LEDc may include sub-elements spaced apart from each other. The third light emitting element LEDc may include a first sub-element LEDc_1 and a second sub-element LEDc_2 spaced apart from each other. For example, each of the first, second, and third light emitting elements LEDa, LEDb, and LEDc may include a first electrode, an intermediate layer, and a second electrode layer E2.

In an embodiment, the second electrode layer E2 may be separated (or disconnected) into second electrodes E2a, E2b, and E2c by the separator SPR. For example, the second electrode layer E2 may be separated (or disconnected) into a second electrode E2a of the first light emitting element LEDa, a second electrode E2b of the second light emitting element LEDb, and a second electrode E2c of the third light emitting element LEDc. The second electrode E2c of the third light emitting element LEDc may be separated (or disconnected) into a second electrode E2c_1 of the first sub-element LEDc_1 and a second electrode E2c_2 of the second sub-element LEDc_2. For example, the second electrode layer E2 may be separated (or disconnected) into the second electrodes E2a, E2b, E2c_1, and E2c_2 by the separator SPR, and the second electrodes E2a, E2b, E2c_1, and E2c_2 may be electrically insulated from each other.

The first, second, and third light emitting elements LEDa, LEDb, and LEDc may emit light of different colors. For example, the first light emitting element LEDa may emit red light, the second light emitting element LEDb may emit green light, and the third light emitting element LEDc may emit blue light. The first and second sub-elements LEDc_1 and LEDc_2 of the third light emitting element LEDc may emit blue light. However, embodiments are not limited thereto.

The first, second, and third light emitting elements LEDa, LEDb, and LEDc may be respectively connected to one of the first, second, and third pixel driving circuits PCa, PCb, and PCc. The first, second, and third light emitting elements LEDa, LEDb, and LEDc may be electrically connected to the first, second, and third pixel driving circuits PCa, PCb, and PCc, respectively. The third pixel driving circuit PCc may be electrically connected to the first and second sub-elements LEDc_1 and LEDc_2 of the third light emitting element LEDc.

In an embodiment, a pixel driving circuit electrically connected to a light emitting element including sub-elements may be disposed between pixel driving circuits electrically connected to other light emitting elements in a plan view. For example, the third pixel driving circuit PCc electrically connected to the third light emitting element LEDc including the first and second sub-elements LEDc_1 and LEDc_2 may be disposed between the first and second pixel driving circuits PCa and PCb respectively connected to the first and second light emitting elements LEDa and LEDb in a plan view. For example, the first pixel driving circuit PCa, the third pixel driving circuit PCc, and the second pixel driving circuit PCb may be sequentially arranged along a first direction DR1. The first pixel driving circuit PCa, the third pixel driving circuit PCc, and the second pixel driving circuit PCb, which are sequentially arranged along the first direction DR1, may define a unit circuit area UCA. For example, the unit circuit area UCA may be defined as a substantially rectangular planar shape, and may be defined in a matrix form along the first direction DR1 and a second direction DR2.

In an embodiment, the display device 11 may include a first unit light emitting area UEA1 and a second unit light emitting area UEA2, and the first and second unit light emitting areas UEA1 and UEA2 may be defined in a matrix form along the first direction DR1 and the second direction DR2. A first light emitting area EAa, a second light emitting area EAb, and a third light emitting area EAc adjacent to each other may be defined in each of the first and second unit light emitting areas UEA1 and UEA2. The first, second, and third light emitting elements LEDa, LEDb, and LEDc may be disposed in the first, second, and third light emitting areas EAa, EAb, and EAc, respectively, and the first, second, and third light emitting areas EAa, EAb, and EAc may be areas in which light is emitted by the first, second, and third light emitting elements LEDa, LEDb, and LEDc, respectively.

In an embodiment, the third light emitting area EAc may include sub-areas spaced apart from each other. The third light emitting area EAc may include a first sub-area EAc_1 and a second sub-area EAc_2, which are spaced apart from each other. For example, the first sub-element LEDc_1 of the third light emitting element LEDc may be disposed in the first sub-area EAc_1, and the first sub-area EAc_1 may be an area in which light is emitted by the first sub-element LEDc_1. The second sub-element LEDc_2 of the third light emitting element LEDc may be disposed in the second sub-area EAc_2, and the second sub-area EAc_2 may be an area in which light is emitted by the second sub-element LEDc_2.

In an embodiment, in each of the first and second unit light emitting areas UEA1 and UEA2, the second sub-element LEDc_2 (or the second sub-area EAc_2) may be spaced apart from the first sub-element LEDc_1 (or the first sub-area EAc_1) in a direction between the first direction DR1 and the second direction DR2 (e.g., a diagonal direction between the first and second directions DR1 and DR2), the first light emitting element LEDa (or the first light emitting area EAa) may be spaced apart from the first sub-element LEDc_1 (or the first sub-area EAc_1) in the second direction DR2, and the second light emitting area LEDb (or the second light emitting area EAb) may be spaced apart from the first sub-element LEDc_1 (or the first sub-area EAc_1) in the first direction DR1.

In an embodiment, the first sub-element LEDc_1 (or the first sub-area EAc_1) may overlap the first pixel driving circuit PCa in a plan view, and the second sub-element LEDc_2 (or the second sub-area EAc_2) may overlap the second pixel driving circuit PCb in a plan view. For example, at least a portion of each of the first sub-element LEDc_1 (or the first sub-area EAc_1) and the first light emitting element LEDa (or the first light emitting area EAa) may overlap the first pixel driving circuit PCa in a plan view, and at least a portion of each of the second sub-element LEDc_2 (or the second sub-area EAc_2) and the second light emitting area LEDb (or the second light emitting area EAb) may overlap the second pixel driving circuit PCb in a plan view. However, embodiments are not limited thereto.

The first and second unit light emitting areas UEA1 and UEA2 may correspond to the unit circuit area UCA. In an embodiment, each of the first and second unit light emitting areas UEA1 and UEA2 may overlap the unit circuit area UCA in a plan view. For example, each first unit light emitting area UEA1 may overlap each unit circuit area UCA as a whole in a plan view, and each second unit light emitting area UEA2 may overlap each unit circuit area UCA as a whole in a plan view.

The first, second, and third light emitting elements LEDa, LEDb, and LEDc may be electrically connected to the first, second, and third pixel driving circuits PCa, PCb, and PCc through the first, second, and third connection electrodes CEa, CEb, and CEc and the first, second, and third connection patterns CNP1, CNP2, and CNP3, respectively. In an embodiment, the first connection electrode CEa and the second connection pattern CNP2 may electrically connect the first light emitting element LEDa to the first pixel driving circuit PCa, the second connection electrode CEb and the third connection pattern CNP3 may electrically connect the second light emitting element LEDb to the second pixel driving circuit PCb, and the third connection electrode CEc and the first connection pattern CNP1 may electrically connect the third light emitting element LEDc to the third pixel driving circuit PCc. For example, the first light emitting element LEDa may be electrically connected to the first pixel driving circuit PCa through the first connection electrode CEa and the second connection pattern CNP2, the second light emitting element LEDb may be electrically connected to the second pixel driving circuit PCb through the second connection electrode CEb and the third connection pattern CNP3, and the third light emitting element LEDc may be electrically connected to the third pixel driving circuit PCc through the third connection electrode CEc and the first connection pattern CNP1.

In an embodiment, the first connection electrode CEa may overlap the first pixel driving circuit PCa in a plan view. For example, the first connection electrode CEa may not overlap the second pixel driving circuit PCb or the third pixel driving circuit PCc in a plan view. The first connection electrode CEa may include a first circuit connection portion CPa and a first light emitting connection portion CNa. The first circuit connection portion CPa may be a portion of the first connection electrode CEa that is electrically connected to the first pixel driving circuit PCa, and the first light emitting connection portion CNa may be a portion of the first connection electrode CEa that is electrically connected to the second connection pattern CNP2. In a plan view, the first light emitting connection portion CNa may not overlap the first light emitting area EAa, and may overlap the separator SPR. For example, the first light emitting connection portion CNa may be disposed below the separator SPR.

The second connection pattern CNP2 may be electrically connected to the first connection electrode CEa. For example, the second connection pattern CNP2 may contact (or may be electrically connected to) the first light emitting connection portion CNa of the first connection electrode CEa. In an embodiment, in a plan view, the second connection pattern CNP2 may not overlap the first light emitting area EAa, and may be adjacent to (e.g., surround) at least a portion of the first light emitting area EAa. For example, the second connection pattern CNP2 may have a closed ring shape that surrounds the first light emitting area EAa as a whole in a plan view, but embodiments are not limited thereto.

The second electrode E2a of the first light emitting element LEDa may be electrically connected to the second connection pattern CNP2. For example, the second electrode E2a of the first light emitting element LEDa may contact the second connection pattern CNP2, and the second connection pattern CNP2 may electrically connect the first connection electrode CEa to the second electrode E2a of the first light emitting element LEDa. The second electrode E2a of the first light emitting element LEDa may be electrically connected to the first pixel driving circuit PCa through the first connection electrode CEa and the second connection pattern CNP2.

In an embodiment, a planar profile of an area in which the second electrode E2a of the first light emitting element LEDa contacts the second connection pattern CNP2 may be substantially the same as or similar to a planar profile of an edge of the second connection pattern CNP2. For example, at least a portion of the second electrode E2a of the first light emitting element LEDa, which contacts the second connection pattern CNP2, and the second connection pattern CNP2 may have a same (or similar) planar profile. For example, in case that the second connection pattern CNP2 has a closed ring shape that surrounds the first light emitting area EAa as a whole in a plan view, an area in which the second electrode E2a of the first light emitting element LEDa contacts the second connection pattern CNP2 may have a closed ring shape in a plan view. For example, the second electrode E2a of the first light emitting element LEDa and the second connection pattern CNP2 may be in contact with each other at a position that does not overlap the first light emitting area EAa in a plan view. Accordingly, the second electrode E2a of the first light emitting element LEDa may be electrically connected to the first pixel driving circuit PCa through the second connection pattern CNP2 and the first connection electrode CEa without reducing a light emitting area of the first light emitting area EAa.

In an embodiment, the second connection electrode CEb may overlap the second pixel driving circuit PCb in a plan view. For example, the second connection electrode CEb may not overlap the first pixel driving circuit PCa or the third pixel driving circuit PCc in a plan view. The second connection electrode CEb may include a second circuit connection portion CPb and a second light emitting connection portion CNb. The second circuit connection portion CPb may be a portion of the second connection electrode CEb that is electrically connected to the second pixel driving circuit PCb, and the second light emitting connection portion CNb may be a portion of the second connection electrode CEb that is electrically connected to the third connection pattern CNP3. In a plan view, the second light emitting connection portion CNb may not overlap the second light emitting area EAb, and may overlap the separator SPR. For example, the second light emitting connection portion CNb may be disposed below the separator SPR.

The third connection pattern CNP3 may be electrically connected to the second connection electrode CEb. For example, the third connection pattern CNP3 may contact (or may be electrically connected to) the second light emitting connection portion CNb of the second connection electrode CEb. In an embodiment, in a plan view, the third connection pattern CNP3 may not overlap the second light emitting area EAb, and may be adjacent to (e.g., surround) at least a portion of the second light emitting area EAb. For example, the third connection pattern CNP3 may have a closed ring shape that surrounds the second light emitting area EAb as a whole in a plan view, but embodiments are not limited thereto.

The second electrode E2b of the second light emitting element LEDb may be electrically connected to the third connection pattern CNP3. For example, the second electrode E2b of the second light emitting element LEDb may contact the third connection pattern CNP3, and the third connection pattern CNP3 may electrically connect the second connection electrode CEb to the second electrode E2b of the second light emitting element LEDb. The second electrode E2b of the second light emitting element LEDb may be electrically connected to the second pixel driving circuit PCb through the second connection electrode CEb and the third connection pattern CNP3.

In an embodiment, a planar profile of an area in which the second electrode E2b of the second light emitting element LEDb contacts the third connection pattern CNP3 may be substantially the same as or similar to a planar profile of an edge of the third connection pattern CNP3. For example, at least a portion of the second electrode E2b of the second light emitting element LEDb, which contacts the third connection pattern CNP3, and the edge of the third connection pattern CNP3 may have a same (or similar) planar profile. For example, in case that the third connection pattern CNP3 has a closed ring shape that surrounds the second light emitting area EAb as a whole in a plan view, an area in which the second electrode E2b of the second light emitting element LEDb contacts the third connection pattern CNP3 may have a closed ring shape in a plan view. For example, the second electrode E2b and the third connection pattern CNP3 of the second light emitting element LEDb may be in contact with each other at a position that does not overlap the second light emitting area EAb in a plan view. Accordingly, the second electrode E2b of the second light emitting element LEDb may be electrically connected to the second pixel driving circuit PCb through the third connection pattern CNP3 and the second connection electrode CEb without reducing a light emitting area of the second light emitting area EAb.

In an embodiment, the third connection electrode CEc may overlap the third pixel driving circuit PCc in a plan view. For example, the third connection electrode CEc may not overlap the first pixel driving circuit PCa or the second pixel driving circuit PCb in a plan view. The third connection electrode CEc may include a third circuit connection portion CPc and a third light emitting connection portion CNc. The third circuit connection portion CPc may be a portion of the third connection electrode CEc that is electrically connected to the third pixel driving circuit PCc, and the third light emitting connection portion CNc may be a portion of the third connection electrode CEc that is electrically connected to the first connection pattern CNP1. In a plan view, the third light emitting connection portion CNc may not overlap the third light emitting area EAc, and may overlap the separator SPR. For example, the third light emitting connection portion CNc may be disposed below the separator SPR.

The first connection pattern CNP1 may be electrically connected to the third connection electrode CEc. For example, the first connection pattern CNP1 may contact (or may be electrically connected to) the third light emitting connection portion CNc of the third connection electrode CEc. The first connection pattern CNP1 may include a first sub-pattern CNP1_1, a second sub-pattern CNP1_2, and a third sub-pattern CNP1_3 electrically connected to each other. For example, the third sub-pattern CNP1_3 may extend from the first sub-pattern CNP1_1 to the second sub-pattern CNP1_2. In an embodiment, the first connection pattern CNP1 may be electrically connected to the third connection electrode CEc through at least one of the first, second, and third sub-patterns CNP1_1, CNP1_2, and CNP1_3. For example, the first sub-pattern CNP1_1 may contact (or may be electrically connected to) the third light emitting connection portion CNc of the third connection electrode CEc, and the second and third sub-patterns CNP1_2 and CNP1_3 may be electrically connected to the third connection electrode CEc through the first sub-pattern CNP1_1.

In an embodiment, in a plan view, the first connection pattern CNP1 may not overlap the third light emitting area EAc, and may be adjacent to (e.g., surround) at least a portion of the third light emitting area EAc. For example, the first sub-pattern CNP1_1 may be a portion of the first connection pattern CNP1 that is adjacent to (e.g., surrounds) at least a portion of the first sub-area EAc_1 in a plan view, the second sub-pattern CNP1_2 may be a portion of the first connection pattern CNP1 that is adjacent to (e.g., surrounds) at least a portion of the second sub-area EAc_2 in a plan view, and the third sub-pattern CNP1_3 may be a portion of the first connection pattern CNP1 that electrically connects the first sub-pattern CNP1_1 and the second sub-pattern CNP1_2. For example, the first sub-pattern CNP1_1 may have a closed ring shape that surrounds the first sub-area EAc_1 as a whole in a plan view, the second sub-pattern CNP1_2 may have a closed ring shape that surrounds the second sub-area EAc_2 as a whole in a plan view, and the third sub-pattern CNP1_3 may have a shape that extends in a direction between the first direction DR1 and the second direction DR2 (e.g., a diagonal direction between the first and second directions DR1 and DR2) in a plan view, but embodiments are not limited thereto.

The second electrode E2c of the third light emitting element LEDc may be electrically connected to the first connection pattern CNP1. For example, the second electrode E2c of the third light emitting element LEDc may contact the first connection pattern CNP1, and the first connection pattern CNP1 may electrically connect the third connection electrode CEc to the second electrode E2c of the third light emitting element LEDc. The second electrode E2c_1 of the first sub-element LEDc_1 may be electrically connected to the first sub-pattern CNP1_1, and the second electrode E2c_2 of the second sub-element LEDc_2 may be electrically connected to the second sub-pattern CNP1_2. For example, the second electrode E2c_1 of the first sub-element LEDc_1 may contact (or may be electrically connected to) the first sub-pattern CNP1_1, the second electrode E2c_2 of the second sub-element LEDc_2 may contact (or may be electrically connected to) the second sub-pattern CNP1_2, and the third connection electrode CEc and the second electrodes E2c_1 and E2c_2 of the first and second sub-elements LEDc_1 and LEDc_2 may be electrically connected to each other through the first sub-pattern CNP1_1.

As a result, the second electrode E2c of the third light emitting element LEDc may be electrically connected to the third pixel driving circuit PCc through the third connection electrode CEc and the first connection pattern CNP1. For example, the second electrodes E2c_1 and E2c_2 of the first and second sub-elements LEDc_1 and LEDc_2 may be electrically connected to the third pixel driving circuit PCc through the third connection electrode CEc and the first connection pattern CNP1.

In an embodiment, a planar profile of an area in which the second electrode E2c of the third light emitting element LEDc contacts the first connection pattern CNP1 may be substantially the same as or similar to a planar profile of edges of the first and second sub-patterns CNP1_1 and CNP1_2 of the first connection pattern CNP1. For example, at least a portion of the second electrode E2c of the third light emitting element LEDc, which contacts the first connection pattern CNP1, and the edges of the first and second sub-patterns CNP1_1 and CNP1_2 of the first connection pattern CNP1 may have a same (or similar) planar profile. For example, a planar profile of an area in which the second electrode E2c_1 of the first sub-element LEDc_1 contacts the first sub-pattern CNP1_1 may be substantially the same as or similar to a planar profile of an edge of the first sub-pattern CNP1_1, and a planar profile of an area in which the second electrode E2c_2 of the second sub-element LEDc_2 contacts the second sub-pattern CNP1_2 may be substantially the same as or similar to a planar profile of an edge of the second sub-pattern CNP1_2. For example, at least a portion of the second electrode E2c_1 of the first sub-element LEDc_1, which contacts the first sub-pattern CNP1_1, and the edge of the first sub-pattern CNP1_1 may have a same (or similar) planar profile, and at least a portion of the second electrode E2c_2 of the second sub-element LEDc_2, which contacts the second sub-pattern CNP1_2, and the edge of the second sub-pattern CNP1_2 may have a same (or similar) planar profile.

For example, in case that the first sub-pattern CNP1_1 has a closed ring shape that surrounds the first sub-area EAc_1 as a whole in a plan view, an area in which the second electrode E2c_1 of the first sub-element LEDc_1 contacts the first sub-pattern CNP1_1 may have a closed ring shape in a plan view. In case that the second sub-pattern CNP1_2 has a closed ring shape that surrounds the second sub-area EAc_2 as a whole in a plan view, an area in which the second electrode E2c_2 of the second sub-element LEDc_2 contacts the second sub-pattern CNP1_2 may have a closed ring shape in a plan view.

For example, the second electrode E2c of the third light emitting element LEDc and the first connection pattern CNP1 may be in contact with each other at a position that does not overlap the third light emitting area EAc in a plan view. For example, the second electrode E2c_1 of the first sub-element LEDc_1 and the first sub-pattern CNP1_1 may be in contact with each other at a position that does not overlap the first sub-area EAc_1 in a plan view, and the second electrode E2c_2 of the second sub-element LEDc_2 and the second sub-pattern CNP1_2 may be in contact with each other at a position that does not overlap the second sub-area EAc_2 in a plan view. Accordingly, the second electrode E2c of the third light emitting element LEDc may be electrically connected to the third pixel driving circuit PCc through the first connection pattern CNP1 and the third connection electrode CEc without reducing a light emitting area of the third light emitting area EAc.

In an embodiment, the first, second, and third connection electrodes CEa, CEb, and CEc may be spaced apart from each other, and may be separate electrodes that are distinguished from each other. For example, the first, second, and third connection electrodes CEa, CEb, and CEc may be electrically insulated from each other. According to embodiments, the arrangement of the first, second, and third pixel driving circuits PCa, PCb, and PCc may be designed such that the first, second, and third connection electrodes CEa, CEb, and CEc are efficiently arranged. For example, the first, second, and third pixel driving circuits PCa, PCb, and PCc may have an optimized arrangement, and the first, second, and third connection electrodes CEa, CEb, and CEc may have an efficient arrangement. For example, the arrangement of the first, second, and third pixel driving circuits PCa, PCb, and PCc may be designed such that lengths (or areas) of the first, second, and third connection electrodes CEa, CEb, and CEc may be minimized. In an embodiment, a pixel driving circuit (e.g., the third pixel driving circuit PCc) electrically connected to a light emitting element including sub-elements (e.g., the third light emitting element LEDc) may be disposed between pixel driving circuits (e.g., the first and second pixel driving circuits PCa and PCb) respectively connected to other light emitting elements (e.g., the first and second light emitting elements LEDa and LEDb) in a plan view. Thus, the lengths of the first, second, and third connection electrodes CEa, CEb, and CEc may be reduced.

In an embodiment, the first, second, and third connection patterns CNP1, CNP2, and CNP3 may be spaced apart from each other, and may be separate patterns that are distinguished from each other. For example, the first, second, and third connection patterns CNP1, CNP2, and CNP3 may be electrically insulated from each other. In an embodiment, the first, second, and third connection patterns CNP1, CNP2, and CNP3 may include a transparent conductive oxide. However, embodiments are not limited thereto, and in an embodiment, the first, second, and third connection patterns CNP1, CNP2, and CNP3 may include a conductive material such as a metal, an alloy, a conductive metal nitride, or the like. These may be used alone or in combination with each other.

In an embodiment, the first, second, and third pixel driving circuits PCa, PCb, and PCc may be designed to be the same, and positions of the first, second, and third circuit connection portions CPa, CPb, and CPc may correspond to each other. For example, the first, second, and third pixel driving circuits PCa, PCb, and PCc may have a same design, and the first, second, and third circuit connection portions CPa, CPb, and CPc may have positions corresponding to the first, second and third circuits PCa, PCb, and PCc, respectively. Accordingly, in case that the first, second, and third pixel driving circuits PCa, PCb, and PCc are formed to have substantially the same size and be disposed along the first direction DR1, a position of the first circuit connection portion CPa, a position of the third circuit connection portion CPc, and a position of the second circuit connection portion CPb may be sequentially disposed along the first direction DR1.

The separator SPR may be disposed on the first, second, and third connection patterns CNP1, CNP2, and CNP3, and may overlap the first, second, and third connection patterns CNP1, CNP2, and CNP3 in a plan view. The separator SPR may cover portions of the first, second, and third connection patterns CNP1, CNP2, and CNP3 and portions of the PDL between adjacent connection patterns. For example, the separator SPR may cover a portion of each of the first and second sub-patterns CNP1_1 and CNP1_2, a portion of each of the second and third connection patterns CNP2 and CNP3, the third sub-pattern CNP1_3, and portions (e.g., portions of the pixel defining layer PDL) between adjacent connection patterns. At least a portion of the separator SPR may extend along edges of the first and second sub-patterns CNP1_1 and CNP1_2 and the second and third connection patterns CNP2 and CNP3 in a plan view. Accordingly, an area in which the second electrode layer E2 contacts the first, second, and third connection patterns CNP1, CNP2, and CNP3 may be adjacent to or overlap an area in which the separator SPR is disposed in a plan view.

The separator SPR may separate (or disconnect) the second electrode layer E2 into the second electrodes E2a, E2b, E2c_1, and E2c_2. The second electrode E2a of the first light emitting element LEDa, the second electrode E2b of the second light emitting element LEDb, the second electrode E2c_1 of the first sub-element LEDc_1 of the third light emitting element LEDc, and the second electrode E2c_2 of the second sub-element LEDc_2 of the third light emitting element LEDc may be electrically insulated from each other by the separator SPR.

The separator SPR may define a first open area OA1, a second open area OA2, a third open area OA3, and a fourth open area OA4 corresponding to the second electrodes E2a, E2b, E2c_1, and E2c_2. For example, the second electrodes E2a, E2b, E2c_1, and E2c_2 may be disposed in the first, second, third, and fourth open areas OA1, OA2, OA3, and OA4, respectively. For example, the separator SPR may have a mesh structure that surrounds the second electrodes E2a, E2b, E2c_1, and E2c_2 in a plan view. For example, the second electrode E2a of the first light emitting element LEDa may be disposed in the third open area OA3 of the separator SPR, the second electrode E2b of the second light emitting element LEDb may be disposed in the fourth open area OA4 of the separator SPR, the second electrode E2c_1 of the first sub-element LEDc_1 of the third light emitting element LEDc may be disposed in the first open area OA1 of the separator SPR, and the second electrode E2c_2 of the second sub-element LEDc_2 of the third light emitting element LEDc may be disposed in the second open area OA2 of the separator SPR.

In an embodiment, a planar shape of the first, second, third, and fourth open areas OA1, OA2, OA3, and OA4 of the separator SPR may be substantially the same as a planar shape of the second electrode layer E2. For example, the first, second, third, and fourth open areas OA1, OA2, OA3, and OA4 of the separator SPR and the second electrode layer E2 may have a same planar shape. For example, a planar shape of the first open area OA1 may be substantially the same as a planar shape of the second electrode E2c_1 of the first sub-element LEDc_1 of the third light emitting element LEDc, a planar shape of the second open area OA2 may be substantially the same as a planar shape of the second electrode E2c_2 of the second sub-element LEDc_2 of the third light emitting element LEDc, a planar shape of the third open area OA3 may be substantially the same as a planar shape of the second electrode E2a of the first light emitting element LEDa, and a planar shape of the fourth open area OA4 may be substantially the same as a planar shape of the second electrode E2b of the second light emitting element LEDb. For example, the first open area OA1 and the second electrode E2c_1 of the first sub-element LEDc_1 of the third light emitting element LEDc may have a same planar shape, the second open area OA2 and the second electrode E2c_2 of the second sub-element LEDc_2 of the third light emitting element LEDc may have a same planar shape, the third open area OA3 and the second electrode E2a of the first light emitting element LEDa may have a same planar shape, and the fourth open area OA4 and the second electrode E2b of the second light emitting element LEDb may have a same planar shape.

In an embodiment, the first, second, third, and fourth open areas OA1, OA2, OA3, and OA4 of the separator SPR may correspond to the first, second, and third connection patterns CNP1, CNP2, and CNP3. For example, the first and second sub-patterns CNP1_1 and CNP1_2 of the first connection pattern CNP1, the second connection pattern CNP2, and the third connection pattern CNP3 may be disposed in the first, second, third, and fourth open areas OA1, OA2, OA3, and OA4, respectively. For example, the first sub-pattern CNP1_1 of the first connection pattern CNP1 may overlap the first open area OA1 in a plan view, the second sub-pattern CNP1_2 of the first connection pattern CNP1 may overlap the second open area OA2 in a plan view, the second connection pattern CNP2 may overlap the third open area OA3 in a plan view, and the third connection pattern CNP3 may overlap the fourth open area OA4 in a plan view.

According to embodiments, the display device 11 may include the third light emitting element LEDc including a first sub-element LEDc_1 and a second sub-element LEDc_2 spaced apart from each other. The third pixel driving circuit PCc electrically connected to the third light emitting element LEDc may be disposed between the first and second pixel driving circuits PCa and PCb respectively connected to the first and second light emitting elements LEDa and LEDb in a plan view. Accordingly, the first, second, and third connection electrodes CEa, CEb, and CEc electrically connecting the second electrode layer E2 to the first, second, and third pixel driving circuits PCa, PCb, and PCc, respectively, may reduce an area they (e.g., the first, second, and third connection electrodes CEa, CEb, and CEc) occupy. Accordingly, parasitic capacitance by the first, second, and third connection electrodes CEa, CEb, and CEc may be reduced, and display quality of the display device 11 may be improved.

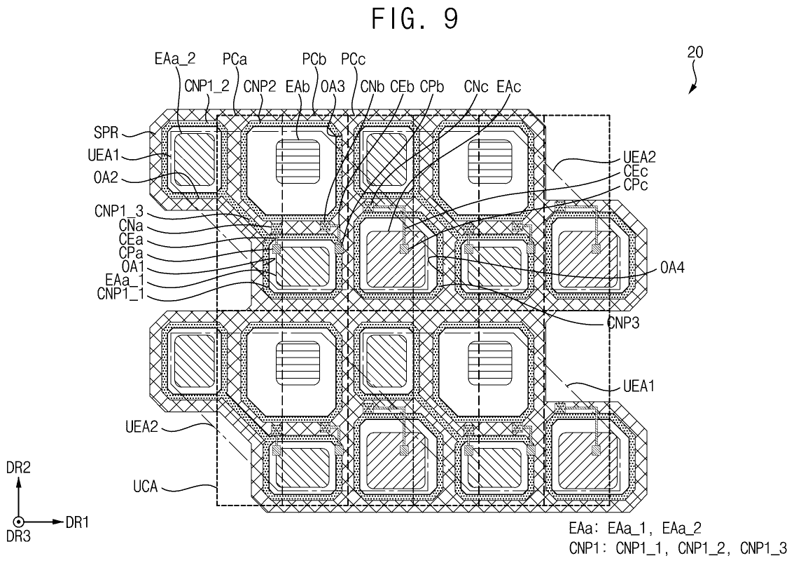

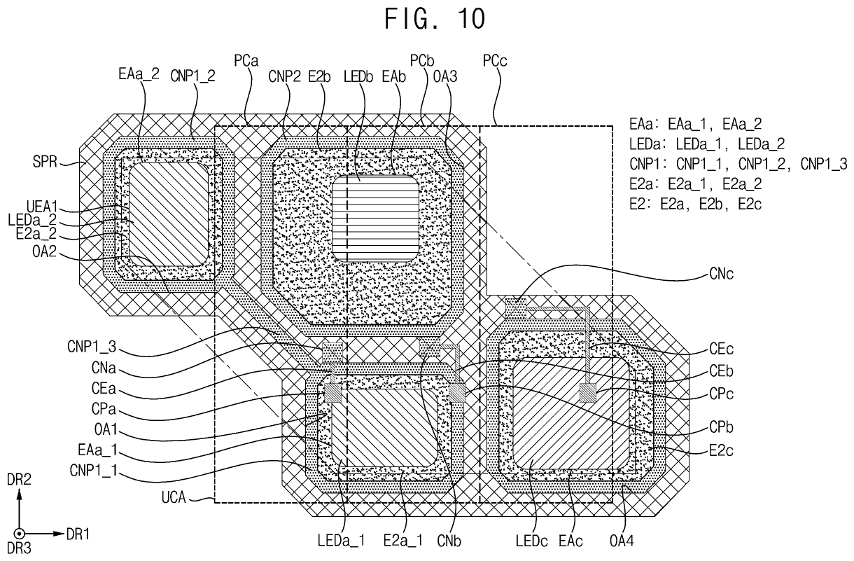

FIG. 9 is a schematic plan view illustrating a display device according to an embodiment of the disclosure. FIG. 10 is a schematic enlarged view illustrating a portion of FIG. 9.

For example, FIG. 9 may correspond to the plan view of FIG. 3, and FIG. 10 may correspond to the enlarged view of FIG. 4. For example, FIG. 9 may be a plan view schematically illustrating a portion of a display device 20, and FIG. 10 may be an enlarged view illustrating a first unit light emitting area UEA1 among unit light emitting areas UEA1 and UEA2 of FIG. 9.

Hereinafter, detailed description of the same or similar constituent elements with the display device 10 described with reference to FIGS. 1A to 6 is omitted or simplified.

Referring to FIGS. 9 and 10, the display device 20 may include a first pixel driving circuit PCa, a second pixel driving circuit PCb, a third pixel driving circuit PCc, a first light emitting element LEDa, a second light emitting element LEDb, a third light emitting element LEDc, a first connection electrode CEa, a second connection electrode CEb, a third connection electrode CEc, a first connection pattern CNP1, a second connection pattern CNP2, a third connection pattern CNP3, and a separator SPR.

Each of the first, second, and third pixel driving circuits PCa, PCb, and PCc may include at least one transistor and at least one capacitor.

In an embodiment, the second pixel driving circuit PCb may be adjacent to the first pixel driving circuit PCa in a first direction DR1, and the third pixel driving circuit PCc may be adjacent to the second pixel driving circuit PCb in the first direction DR1. The first, second, and third pixel driving circuits PCa, PCb, and PCc may be sequentially arranged along the first direction DR1. The first, second, and third pixel driving circuits PCa, PCb, and PCc, which are sequentially arranged along the first direction DR1, may define a unit circuit area UCA. For example, the unit circuit area UCA may be defined as a substantially rectangular planar shape. The unit circuit area UCA may be defined in a matrix form along the first direction DR1 and a second direction DR2.

At least one of the first, second, and third light emitting elements LEDa, LEDb, and LEDc may include sub-elements spaced apart from each other. In an embodiment, the first light emitting element LEDa may include sub-elements spaced apart from each other. The first light emitting element LEDa may include a first sub-element LEDa_1 and a second sub-element LEDa_2, which are spaced apart from each other. For example, each of the first, second, and third light emitting elements LEDa, LEDb, and LEDc may include a first electrode, an intermediate layer, and a second electrode layer E2.

In an embodiment, the second electrode layer E2 may be separated (or disconnected) into a second electrode E2a of the first light emitting element LEDa, a second electrode E2b of the second light emitting element LEDb, and a second electrode E2c of the third light emitting element LEDc by the separator SPR. The second electrode E2a of the first light emitting element LEDa_1 may be separated (or disconnected) into a second electrode E2a_1 of the first sub-element LEDa_1 and a second electrode E2a_2 of the second sub-element LEDa_2. The second electrodes E2a_1, E2a_2, E2b, and E2c may be electrically insulated from each other.

The first, second, and third light emitting elements LEDa, LEDb, and LEDc may be respectively connected to one of the first, second, and third pixel driving circuits PCa, PCb, and PCc. The first, second, and third light emitting elements LEDa, LEDb, and LEDc may be electrically connected to the first, second, and third pixel driving circuits PCa, PCb, and PCc, respectively. The first pixel driving circuit PCa may be electrically connected to the first and second sub-elements LEDa_1 and LEDa_2 of the first light emitting element LEDa.

In an embodiment, the display device 20 may include a first unit light emitting area UEA1 and a second unit light emitting area UEA2, and the first and second unit light emitting areas UEA1 and UEA2 may be defined in a matrix form along the first direction DR1 and the second direction DR2. A first light emitting area EAa, a second light emitting area EAb, and a third light emitting area EAc adjacent to each other may be defined in each of the first and second unit light emitting areas UEA1 and UEA2. The first, second, and third light emitting elements LEDa, LEDb, and LEDc may be disposed in the first, second, and third light emitting areas EAa, EAb, and EAc, respectively, and the first, second, and third light emitting areas EAa, EAb, and EAc may be areas in which light is emitted by the first, second, and third light emitting elements LEDa, LEDb, and LEDc, respectively.

In an embodiment, the first light emitting area EAa may include sub-areas spaced apart from each other. The first light emitting area EAa may include a first sub-area EAa_1 and a second sub-area EAa_2, which are spaced apart from each other. The first and second sub-elements LEDa_1 and LEDa_2 of the first light emitting element LEDa may be disposed in the first and second sub-areas EAa_1 and EAa_2, respectively, and the first and second sub-areas EAa_1 and EAa_2 may be areas in which light is emitted by the first and second sub-elements LEDa_1 and LEDa_2, respectively.

In an embodiment, each of the first and second unit light emitting areas UEA1 and UEA2 may be defined as a planar shape of a polygon (e.g., a hexagon). For example, each of the first and second unit light emitting areas UEA1 and UEA2 may be defined as a rectangular planar shape in which corners facing each other in a direction between the first direction DR1 and the second direction DR2 (e.g., a diagonal direction between the first and second directions DR1 and DR2) are cut off (or chamfered).

In an embodiment, in each of the first and second unit light emitting areas UEA1 and UEA2, the second sub-element LEDa_2 (or the second sub-area EAa_2) may be spaced apart from the first sub-element LEDa_1 (or the first sub-area EAa_1) in a direction between a direction opposite to the first direction DR1 and the second direction DR2 (e.g., a diagonal direction between an opposite direction to the first direction DR1 and the second direction DR2), the second light emitting element LEDb (or the second light emitting area EAb) may be spaced apart from the first sub-element LEDa_1 (or the first sub-area EAa_1) in the second direction DR2, and the third light emitting area LEDc (or the third light emitting area EAc) may be spaced apart from the first sub-element LEDa_1 (or the first sub-area EAa_1) in the first direction DR1.

In an embodiment, the first sub-element LEDa_1 (or the first sub-area EAa_1) may overlap the second pixel driving circuit PCb in a plan view. For example, at least a portion of each of the first sub-element LEDa_1 (or the first sub-area EAa_1) and the second light emitting element LEDb (or the second light emitting area EAb) may overlap the second pixel driving circuit PCb in a plan view, and at least a portion of the third light emitting element LEDc (or the third light emitting area EAc) may overlap the third pixel driving circuit PCc in a plan view. However, embodiments are not limited thereto.

The first and second unit light emitting areas UEA1 and UEA2 may correspond to the unit circuit area UCA. In an embodiment, each of the first and second unit light emitting areas UEA1 and UEA2 may partially overlap the unit circuit area UCA in a plan view. For example, each first unit light emitting area UEA1 may partially overlap each unit circuit area UCA in a plan view, and each second unit light emitting area UEA2 may partially overlap each unit circuit area UCA in a plan view. For example, in a plan view, a portion of the unit circuit area UCA may overlap the first unit light emitting area UEA1, and another portion of the unit circuit area UCA may overlap the second unit light emitting area UEA2.

The first, second, and third light emitting elements LEDa, LEDb, and LEDc may be electrically connected to the first, second, and third pixel driving circuits PCa, PCb, and PCc through the first, second, and third connection electrodes CEa, CEb, and CEc and the first, second, and third connection patterns CNP1, CNP2, and CNP3, respectively. In an embodiment, the first connection electrode CEa and the first connection pattern CNP1 may electrically connect the first light emitting element LEDa to the first pixel driving circuit PCa, the second connection electrode CEb and the second connection pattern CNP2 may electrically connect the second light emitting element LEDb to the second pixel driving circuit PCb, and the third connection electrode CEc and the third connection pattern CNP3 may electrically connect the third light emitting element LEDc to the third pixel driving circuit PCc. For example, the first light emitting element LEDa may be electrically connected to the first pixel driving circuit PCa through the first connection electrode CEa and the first connection pattern CNP1, the second light emitting element LEDb may be electrically connected to the second pixel driving circuit PCb through the second connection electrode CEb and the second connection pattern CNP2, and the third light emitting element LEDc may be electrically connected to the third pixel driving circuit PCc through the third connection electrode CEc and the third connection pattern CNP3.

In an embodiment, the first connection electrode CEa may overlap the first pixel driving circuit PCa in a plan view. The first connection electrode CEa may include a first circuit connection portion CPa and a first light emitting connection portion CNa. The first circuit connection portion CPa may be a portion of the first connection electrode CEa that is electrically connected to the first pixel driving circuit PCa, and the first light emitting connection portion CNa may be a portion of the first connection electrode CEa that is electrically connected to the first connection pattern CNP1.

The first connection pattern CNP1 may be electrically connected to the first connection electrode CEa. For example, the first connection pattern CNP1 may contact (or may be electrically connected to) the first light emitting connection portion CNa of the first connection electrode CEa. The first connection pattern CNP1 may include a first sub-pattern CNP1_1, a second sub-pattern CNP1_2, and a third sub-pattern CNP1_3 electrically connected to each other. For example, the third sub-pattern CNP1_3 may extend from the first sub-pattern CNP1_1 to the second sub-pattern CNP1_2. In an embodiment, the first connection pattern CNP1 may be electrically connected to the first connection electrode CEa through at least one of the first, second, and third sub-patterns CNP1_1, CNP1_2, and CNP1_3. For example, the first sub-pattern CNP1_1 may contact (or may be electrically connected to) the first light emitting connection portion CNa, and the second and third sub-patterns CNP1_2 and CNP1_3 may be electrically connected to the first connection electrode CEa through the first sub-pattern CNP1_1.

In an embodiment, in a plan view, the first connection pattern CNP1 may not overlap the first light emitting area EAa, and may be adjacent to (e.g., surround) at least a portion of the first light emitting area EAa. For example, the first sub-pattern CNP1_1 may be a portion of the first connection pattern CNP1 that is adjacent to (e.g., surrounds) at least a portion of the first sub-area EAa_1 in a plan view, the second sub-pattern CNP1_2 may be a portion of the first connection pattern CNP1 that is adjacent to (e.g., surrounds) at least a portion of the second sub-area EAa_2 in a plan view, and the third sub-pattern CNP1_3 may be a portion of the first connection pattern CNP1 that electrically connects the first sub-pattern CNP1_1 and the second sub-pattern CNP1_2. For example, the first sub-pattern CNP1_1 may be electrically connected to the second sub-pattern CNP1_2 through the third sub-pattern CNP1_3.

The second electrode E2a of the first light emitting element LEDa may be electrically connected to the first connection pattern CNP1. For example, the second electrode E2a of the first light emitting element LEDa may contact the first connection pattern CNP1, and may be electrically connected to the first connection electrode CEa through the first connection pattern CNP1. The second electrodes E2a_1 and E2a_2 of the first and second sub-elements LEDa_1 and LEDa_2 may be electrically connected to the first and second sub-patterns CNP1_1 and CNP1_2, respectively. For example, the second electrodes E2a_1 and E2a_2 of the first and second sub-elements LEDa_1 and LEDa_2 may respectively contact the first and second sub-patterns CNP1_1 and CNP1_2, and may be electrically connected to the first connection electrode CEa through the first connection pattern CNP1.

In an embodiment, a planar profile of an area in which the second electrodes E2a of the first light emitting element LEDa contacts the first connection pattern CNP1 (i.e., an area in which the second electrodes E2a_1 and E2a_2 of the first and second sub-elements LEDa_1 and LEDa_2 contact the first and second sub-patterns CNP1_1 and CNP1_2) may be substantially the same as or similar to a planar profile of edges of the first and second sub-patterns CNP1_1 and CNP1_2 of the first connection pattern CNP1. For example, at least a portion of the second electrodes E2a of the first light emitting element LEDa, which contacts the first connection pattern CNP1 (i.e., an area in which the second electrodes E2a_1 and E2a_2 of the first and second sub-elements LEDa_1 and LEDa_2 contact the first and second sub-patterns CNP1_1 and CNP1_2) and the edges of the first and second sub-patterns CNP1_1 and CNP1_2 of the first connection pattern CNP1 may have a same (or similar) planar profile. For example, the second electrode E2a of the first light emitting element LEDa and the first connection pattern CNP1 may be in contact with each other at a position that does not overlap the first light emitting area EAa in a plan view. For example, the second electrodes E2a_1 and E2a_2 of the first and second sub-elements LEDa_1 and LEDa_2 and the first and second sub-patterns CNP1_1 and CNP1_2 may be in contact with each other at a position that does not overlap the first sub-area EAa_1 or the second sub-area EAa_2 in a plan view, respectively.

As a result, the second electrodes E2a (i.e., the second electrodes E2a_1 and E2a_2 of the first and second sub-elements LEDa_1 and LEDa_2) may be electrically connected to the first pixel driving circuit PCa through the first connection pattern CNP1 and the first connection electrode CEa without reducing a light emitting area of the first light emitting area EAa.

In an embodiment, the second connection electrode CEb may overlap the second pixel driving circuit PCb in a plan view. The second connection electrode CEb may include a second circuit connection portion CPb and a second light emitting connection portion CNb. The second circuit connection portion CPb may be a portion of the second connection electrode CEb that is electrically connected to the second pixel driving circuit PCb, and the second light emitting connection portion CNb may be a portion of the second connection electrode CEb that is electrically connected to the second connection pattern CNP2.

The second connection pattern CNP2 may be electrically connected to the second connection electrode CEb. For example, the second connection pattern CNP2 may contact (or may be electrically connected to) the second light emitting connection portion CNb of the second connection electrode CEb. In an embodiment, in a plan view, the second connection pattern CNP2 may not overlap the second light emitting area EAb, and may be adjacent to (e.g., surround) at least a portion of the second light emitting area EAb.

The second electrode E2b of the second light emitting element LEDb may be electrically connected to the second connection pattern CNP2. For example, the second electrode E2b of the second light emitting element LEDb may contact the second connection pattern CNP2, and may be electrically connected to the second connection electrode CEb through the second connection pattern CNP2. In an embodiment, a planar profile of an area in which the second electrode E2b of the second light emitting element LEDb contacts the second connection pattern CNP2 may be substantially the same as or similar to a planar profile of an edge of the second connection pattern CNP2. For example, at least a portion of the second electrode E2b of the second light emitting element LEDb, which contacts the second connection pattern CNP2, and the edge of the second connection pattern CNP2 may have a same (or similar) planar profile. For example, the second electrode E2b of the second light emitting element LEDb and the second connection pattern CNP2 may be in contact with each other at a position that does not overlap the second light emitting area EAb in a plan view. As a result, the second electrode E2b of the second light emitting element LEDb may be electrically connected to the second pixel driving circuit PCb through the second connection electrode CEb and the second connection pattern CNP2 without reducing a light emitting area of the second light emitting area EAb.

In an embodiment, the third connection electrode CEc may overlap the third pixel driving circuit PCc in a plan view. The third connection electrode CEc may include a third circuit connection portion CPc and a third light emitting connection portion CNc. The third circuit connection portion CPc may be a portion of the third connection electrode CEc that is electrically connected to the third pixel driving circuit PCc, and the third light emitting connection portion CNc may be a portion of the third connection electrode CEc that is electrically connected to the third connection pattern CNP3.

The third connection pattern CNP3 may be electrically connected to the third connection electrode CEc. For example, the third connection pattern CNP3 may contact (or may be electrically connected to) the third light emitting connection portion CNc of the third connection electrode CEc. In an embodiment, in a plan view, the third connection pattern CNP3 may not overlap the third light emitting area EAc, and may be adjacent to (e.g., surround) at least a portion of the third light emitting area EAc.

The second electrode E2c of the third light emitting element LEDc may be electrically connected to the third connection pattern CNP3. For example, the second electrode E2c of the third light emitting element LEDc may contact the third connection pattern CNP3, and may be electrically connected to the third connection electrode CEc through the third connection pattern CNP3. In an embodiment, a planar profile of an area in which the second electrode E2c of the third light emitting element LEDc contacts the third connection pattern CNP3 may be substantially the same as or similar to a planar profile of an edge of the third connection pattern CNP3. For example, at least a portion of the second electrode E2c of the third light emitting element LEDc, which contacts the third connection pattern CNP3, and the edge of the third connection pattern CNP3 may have a same (or similar) planar profile. For example, the second electrode E2c of the third light emitting element LEDc and the third connection pattern CNP3 may be in contact with each other at a position that does not overlap the third light emitting area EAc in a plan view. As a result, the second electrode E2c of the third light emitting element LEDc may be electrically connected to the third pixel driving circuit PCc through the third connection electrode CEc and the third connection pattern CNP3 without reducing a light emitting area of the third light emitting area EAc.

In an embodiment, the first, second, and third connection electrodes CEa, CEb, and CEc may be spaced apart from each other, and may be separate electrodes that are distinguished from each other. For example, the first, second, and third connection electrodes CEa, CEb, and CEc may be electrically insulated from each other. The first, second, and third connection patterns CNP1, CNP2, and CNP3 may be spaced apart from each other, and may be separate patterns that are distinguished from each other. For example, the first, second, and third connection patterns CNP1, CNP2, and CNP3 may be electrically insulated from each other.

In an embodiment, the first, second, and third connection patterns CNP1, CNP2, and CNP3 may include a transparent conductive oxide. However, embodiments are not limited thereto, and in an embodiment, the first, second, and third connection patterns CNP1, CNP2, and CNP3 may include a conductive material such as a metal, an alloy, a conductive metal nitride, or the like. These may be used alone or in combination with each other.

According to embodiments, the shapes of the first and second unit light emitting areas UEA1 and UEA2 respectively corresponding to the unit circuit area UCA may be designed such that the first, second, and third connection electrodes CEa, CEb, and CEc electrically connecting the second electrode layer E2 to the first, second, and third pixel driving circuits PCa, PCb, and PCc, respectively, may be efficiently arranged. For example, even when the arrangement of the pixel driving circuits may not be changed (e.g., when the arrangement in which the first, second, and third pixel driving circuits PCa, PCb, and PCc are arranged along the first direction DR1 cannot be changed), the shapes of the first and second unit light emitting areas UEA1 and UEA2 may be designed such that lengths (or areas) of the first, second, and third connection electrodes CEa, CEb, and CEc may be minimized. For example, the first and second unit areas UEA1 and UEA2 may have optimized shapes without change of the arrangement of the first, second, and third pixel driving circuits PCa, PCb, and PCc along the first direction DR1, and the lengths (or the areas) of the first, second, and third connection electrodes CEa, CEb, and CEc may be decreased). In an embodiment, as the first, second, and third pixel driving circuits PCa, PCb, and PCc are arranged along the first direction DR1, and each of the first and second unit light emitting areas UEA1 and UEA2 is defined as a planar shape of a polygon (e.g., a rectangle in which corners facing in a diagonal direction are cut off), the lengths of the first, second, and third connection electrodes CEa, CEb, and CEc may be reduced.

The separator SPR may overlap the first, second, and third connection patterns CNP1, CNP2, and CNP3 in a plan view, and may cover portions of the first, second, and third connection patterns CNP1, CNP2, and CNP3 and portions (e.g., portions of the pixel defining layer PDL) between adjacent connection patterns. An area in which the second electrode layer E2 contacts the first, second, and third connection patterns CNP1, CNP2, and CNP3 may be adjacent to or overlap an area in which the separator SPR is disposed in a plan view. The separator SPR may overlap the first, second, and third light emitting connection portions CNa, CNb, and CNc of the first, second, and third connection patterns CNP1, CNP2, and CNP3 in a plan view. For example, the first, second, and third connection patterns CNP1, CNP2, and CNP3 may be disposed below the separator SPR, and may not overlap the first, second, and third light emitting areas EAa, EAb, and EAc in a plan view, respectively.

The separator SPR may define a first open area OA1, a second open area OA2, a third open area OA3, and a fourth open area OA4 corresponding to the second electrodes E2a_1, E2a_2, E2b, and E2c, respectively. For example, the second electrodes E2a_1, E2a_2, E2b, and E2c may be disposed in the first, second, third, and fourth open areas OA1, OA2, OA3, and OA4, respectively. For example, the second electrode E2a_1 of the first sub-element LEDa_1 of the first light emitting element LEDa may be disposed in the first open area OA1, the second electrode E2a_2 of the second sub-element LEDa_2 of the first light emitting element LEDa may be disposed in the second open area OA2, the second electrode E2b of the second light emitting element LEDb may be disposed in the third open area OA3, and the second electrode E2c of the third light emitting element LEDc may be disposed in the fourth open area OA4. In an embodiment, a planar shape of the first, second, third, and fourth open areas OA1, OA2, OA3, and OA4 of the separator SPR may be substantially the same as a planar shape of the second electrodes E2a_1, E2a_2, E2b, and E2c. For example, the first, second, third, and fourth open areas OA1, OA2, OA3, and OA4 of the separator SPR and the second electrodes E2a_1, E2a_2, E2b, and E2c may have a same planar shape.

In an embodiment, the first, second, third, and fourth open areas OA1, OA2, OA3, and OA4 of the separator SPR may correspond to the first, second, and third connection patterns CNP1, CNP2, and CNP3. For example, the first and second sub-patterns CNP1_1 and CNP1_2 of the first connection pattern CNP1, the second connection pattern CNP2, and the third connection pattern CNP3 may be disposed in the first, second, third, and fourth open areas OA1, OA2, OA3, and OA4, respectively. For example, the first and second sub-patterns CNP1_1 and CNP1_2 and the second and third connection patterns CNP2 and CNP3 may overlap the first, second, third, and fourth open areas OA1, OA2, OA3, and OA4 in a plan view, respectively.

According to embodiments, the display device 20 may include the first and second unit light emitting areas UEA1 and UEA2 partially overlapping the corresponding unit circuit area UCA in a plan view. The shape of each of the first and second unit light emitting areas UEA1 and UEA2 may be formed such that an area occupied by the first, second, and third connection electrodes CEa, CEb, and CEc electrically connecting the second electrode layer E2 to the first, second, and third pixel driving circuits PCa, PCb, and PCc, respectively, is reduced. For example, each of the first and second unit light emitting areas UEA1 and UEA2 may be defined as a rectangular planar shape in which corners facing each other in a diagonal direction are cut off (or chamfered). Accordingly, parasitic capacitance by the first, second, and third connection electrodes CEa, CEb, and CEc may be reduced, and display quality of the display device 20 may be improved.

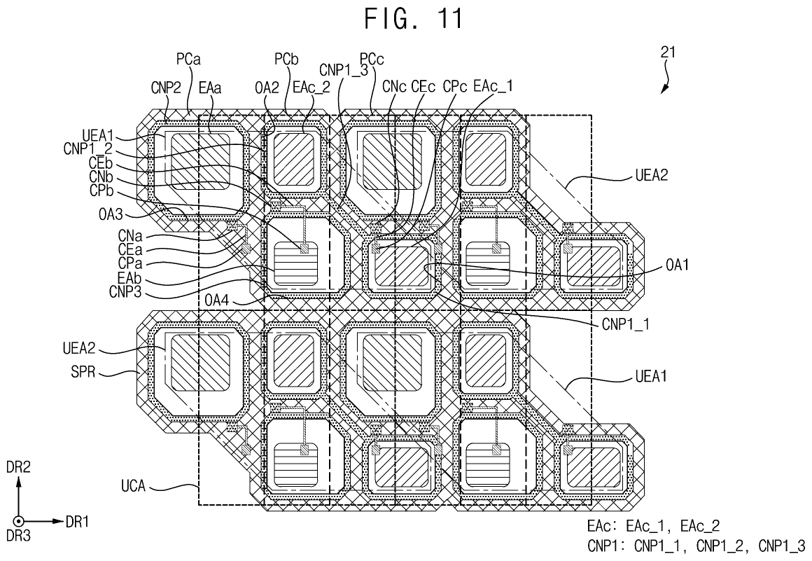

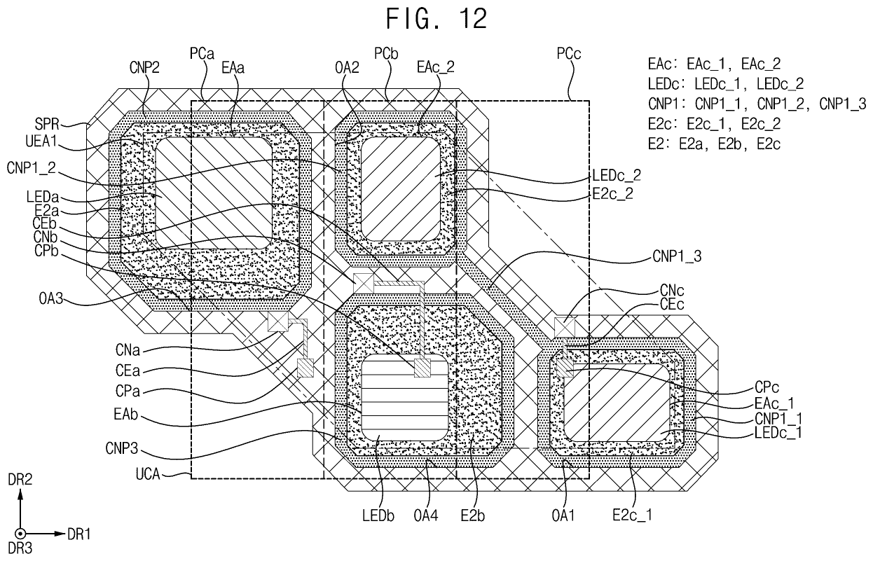

FIG. 11 is a schematic plan view illustrating a display device according to an embodiment of the disclosure. FIG. 12 is a schematic enlarged view illustrating a portion of FIG. 11.

For example, FIG. 11 may correspond to the plan view of FIG. 3, and FIG. 12 may correspond to the enlarged view of FIG. 4. For example, FIG. 11 may be a plan view schematically illustrating a portion of a display device 21, and FIG. 12 may be an enlarged view illustrating a first unit light emitting area UEA1 among unit light emitting areas UEA1 and UEA2 of FIG. 11.

Hereinafter, detailed description of the same or similar constituent elements with the display device 10 described with reference to FIGS. 1A to 6 and the display device 20 described with reference to FIGS. 9 and 10 is omitted or simplified.

Referring to FIGS. 11 and 12, the display device 21 may include a first pixel driving circuit PCa, a second pixel driving circuit PCb, a third pixel driving circuit driving PCc, a first light emitting element LEDa, a second light emitting element LEDb, a third light emitting element LEDc, a first connection electrode CEa, a second connection electrode CEb, a third connection electrode CEc, a first connection pattern CNP1, a second connection pattern CNP2, a third connection pattern CNP3, and a separator SPR.

Each of the first, second, and third pixel driving circuits PCa, PCb, and PCc may include at least one transistor and at least one capacitor.

In an embodiment, the second pixel driving circuit PCb may be adjacent to the first pixel driving circuit PCa in a first direction DR1, and the third pixel driving circuit PCc may be adjacent to the second pixel driving circuit PCb in the first direction DR1. The first, second, and third pixel driving circuits PCa, PCb, and PCc may be sequentially arranged along the first direction DR1. The first, second, and third pixel driving circuits PCa, PCb, and PCc, which are sequentially arranged along the first direction DR1, may define a unit circuit area UCA. For example, the unit circuit area UCA may be defined as a substantially rectangular planar shape, and may be defined in a matrix form along the first direction DR1 and a second direction DR2.

At least one of the first, second, and third light emitting elements LEDa, LEDb, and LEDc may include sub-elements spaced apart from each other. In an embodiment, the third light emitting element LEDc may include sub-elements spaced apart from each other. The third light emitting element LEDc may include a first sub-element LEDc_1 and a second sub-element LEDc_2 spaced apart from each other. For example, each of the first, second, and third light emitting elements LEDa, LEDb, and LEDc may include a first electrode, an intermediate layer, and a second electrode layer E2.

In an embodiment, the second electrode layer E2 may be separated (or disconnected) into a second electrode E2a of the first light emitting element LEDa, a second electrode E2b of the second light emitting element LEDb, and a second electrode E2c of the third light emitting element LEDc by the separator SPR. The second electrode E2c of the third light emitting element LEDc may be separated (or disconnected) into a second electrode E2c_1 of the first sub-element LEDc_1 and a second electrode E2c_2 of the second sub-element LEDc_2. The second electrodes E2a, E2b, E2c_1, and E2c_2 may be electrically insulated from each other.

The first, second, and third light emitting elements LEDa, LEDb, and LEDc may be respectively connected to one of the first, second, and third pixel driving circuits PCa, PCb, and PCc. The first, second, and third light emitting elements LEDa, LEDb, and LEDc may be electrically connected to the first, second, and third pixel driving circuits PCa, PCb, and PCc, respectively. The third pixel driving circuit PCc may be electrically connected to the first and second sub-elements LEDc_1 and LEDc_2 of the third light emitting element LEDc.

In an embodiment, the display device 21 may include a first unit light emitting area UEA1 and a second unit light emitting area UEA2, and the first and second unit light emitting areas UEA1 and UEA2 may be defined in a matrix form along the first direction DR1 and the second direction DR2. A first light emitting area EAa, a second light emitting area EAb, and a third light emitting area EAc adjacent to each other may be defined in each of the first and second unit light emitting areas UEA1 and UEA2. The first, second, and third light emitting elements LEDa, LEDb, and LEDc may be disposed in the first, second, and third light emitting areas EAa, EAb, and EAc, respectively, and the first, second, and third light emitting areas EAa, EAb, and EAc may be areas in which light is emitted by the first, second, and third light emitting elements LEDa, LEDb, and LEDc, respectively. For example, the light generated by the first, second, and third light emitting elements LEDa, LEDb, and LEDc may be emitted from the first, second, and third light emitting areas EAa, EAb, and EAc, respectively.

In an embodiment, the third light emitting area EAc may include sub-areas spaced apart from each other. The third light emitting area EAc may include a first sub-area EAc_1 and a second sub-area EAc_2, which are spaced apart from each other. The first and second sub-elements LEDc_1 and LEDc_2 of the third light emitting element LEDc may be disposed in the first and second sub-areas EAc_1 and EAc_2, respectively, and the first and second sub-areas EAc_1 and EAc_2 may be areas in which light is emitted by the first and second sub-elements LEDc_1 and LEDc_2, respectively. For example, the light generated by the first and second sub-elements LEDc_1 and LEDc_2 may be emitted from the first and second sub-areas EAc_1 and EAc_2, respectively.

In an embodiment, each of the first and second unit light emitting areas UEA1 and UEA2 may be defined as a planar shape of a polygon (e.g., a hexagon). For example, each of the first and second unit light emitting areas UEA1 and UEA2 may be defined as a rectangular planar shape in which corners facing each other in a direction between the first direction DR1 and the second direction DR2 (e.g., a diagonal direction between the first direction DR1 and the second direction DR2) are cut off (or chamfered).

In an embodiment, in each of the first and second unit light emitting areas UEA1 and UEA2, the second sub-element LEDc_2 (or the second sub-area EAc_2) may be spaced apart from the first sub-element LEDc_1 (or the first sub-area EAc_1) in a direction between a direction opposite to the first direction DR1 and the second direction DR2 (e.g., a diagonal direction between an opposite direction to the first direction DR1 and the second direction DR2), the first light emitting area LEDa (or the first light emitting area EAa) may be spaced apart from the second sub-element LEDc_2 (or the second sub-area EAc_2) in the direction opposite to the first direction DR1, and the second light emitting area LEDb (or the second light emitting area EAb) may be spaced apart from the first sub-element LEDc_1 (or the first sub-area EAc_1) in the direction opposite to the first direction DR1.

In an embodiment, the second sub-element LEDc_2 (or the second sub-area EAc_2) may overlap the second pixel driving circuit PCb in a plan view. For example, at least a portion of each of the second sub-element LEDc_2 (or the second sub-area EAc_1) and the second light emitting element LEDb (or the second light emitting area EAb) may overlap the second pixel driving circuit PCb in a plan view, and at least a portion of the first light emitting element LEDa (or the first light emitting area EAa) may overlap the first pixel driving circuit PCa in a plan view. However, embodiments are not limited thereto.

The first and second unit light emitting areas UEA1 and UEA2 may correspond to the unit circuit area UCA. In an embodiment, each of the first and second unit light emitting areas UEA1 and UEA2 may partially overlap the unit circuit area UCA in a plan view. For example, each first unit light emitting area UEA1 may partially overlap each unit circuit area UCA in a plan view, and each second unit light emitting area UEA2 may partially overlap each unit circuit area UCA in a plan view.

The first, second, and third light emitting elements LEDa, LEDb, and LEDc may be electrically connected to the first, second, and third pixel driving circuits PCa, PCb, and PCc through the first, second, and third connection electrodes CEa, CEb, CEc and the first, second, and third connection patterns CNP1, CNP2, and CNP3, respectively. In an embodiment, the first connection electrode CEa and the second connection pattern CNP2 may electrically connect the first light emitting element LEDa to the first pixel driving circuit PCa, the second connection electrode CEb and the third connection pattern CNP3 may electrically connect the second light emitting element LEDb to the second pixel driving circuit PCb, and the third connection electrode CEc and the first connection pattern CNP1 may electrically connect the third light emitting element LEDc to the third pixel driving circuit PCc. For example, the first light emitting element LEDa may be electrically connected to the first pixel driving circuit PCa through the first connection electrode CEa and the second connection pattern CNP2, the second light emitting element LEDb may be electrically connected to the second pixel driving circuit PCb through the second connection electrode CEb and the third connection pattern CNP3, and the third light emitting element LEDc may be electrically connected to the third pixel driving circuit PCc through the third connection electrode CEc and the first connection pattern CNP1.

In an embodiment, the first connection electrode CEa may overlap the first pixel driving circuit PCa in a plan view. The first connection electrode CEa may include a first circuit connection portion CPa and a first light emitting connection portion CNa. The first circuit connection portion CPa may be a portion of the first connection electrode CEa that is electrically connected to the first pixel driving circuit PCa, and the first light emitting connection portion CNa may be a portion of the first connection electrode CEa that is electrically connected to the second connection pattern CNP2.

The second connection pattern CNP2 may be electrically connected to the first connection electrode CEa. For example, the second connection pattern CNP2 may contact (or may be electrically connected to) the first light emitting connection portion CNa of the first connection electrode CEa. In an embodiment, in a plan view, the second connection pattern CNP2 may not overlap the first light emitting area EAa, and may be adjacent to (e.g., surround) at least a portion of the first light emitting area EAa.

The second electrode E2a of the first light emitting element LEDa may be electrically connected to the second connection pattern CNP2. For example, the second electrode E2a of the first light emitting element LEDa may contact the second connection pattern CNP2, and may be electrically connected to the first connection electrode CEa through the second connection pattern CNP2. In an embodiment, a planar profile of an area in which the second electrode E2a of the first light emitting element LEDa contacts the second connection pattern CNP2 may be substantially the same as or similar to a planar profile of an edge of the second connection pattern CNP2. For example, at least a portion of the second electrode E2a of the first light emitting element LEDa, which contacts the second connection pattern CNP2, and the edge of the second connection pattern CNP2 may have a same (or similar) planar profile. For example, the second electrode E2a of the first light emitting element LEDa and the second connection pattern CNP2 may be in contact with each other at a position that does not overlap the first light emitting area EAa in a plan view. As a result, the second electrode E2a of the first light emitting element LEDa may be electrically connected to the first pixel driving circuit PCa through the first connection electrode CEa and the second connection pattern CNP2 without reducing a light emitting area of the first light emitting area EAa.

In an embodiment, the second connection electrode CEb may overlap the second pixel driving circuit PCb in a plan view. The second connection electrode CEb may include a second circuit connection portion CPb and a second light emitting connection portion CNb. The second circuit connection portion CPb may be a portion of the second connection electrode CEb that is electrically connected to the second pixel driving circuit PCb, and the second light emitting connection portion CNb may be a portion of the second connection electrode CEb that is electrically connected to the third connection pattern CNP3.

The third connection pattern CNP3 may be electrically connected to the second connection electrode CEb. For example, the third connection pattern CNP3 may contact (or may be electrically connected to) the second light emitting connection portion CNb of the second connection electrode CEb. In an embodiment, in a plan view, the third connection pattern CNP3 may not overlap the second light emitting area EAb, and may be adjacent to (e.g., surround) at least a portion of the second light emitting area EAb.

The second electrode E2b of the second light emitting element LEDb may be electrically connected to the third connection pattern CNP3. For example, the second electrode E2b of the second light emitting element LEDb may contact the third connection pattern CNP3, and may be electrically connected to the second connection electrode CEb through the third connection pattern CNP3. In an embodiment, a planar profile of an area in which the second electrode E2b of the third light emitting element LEDb contacts the third connection pattern CNP3 may be substantially the same as or similar to a planar profile of an edge of the third connection pattern CNP3. For example, at least a portion of the second electrode E2b of the third light emitting element LEDb, which contacts the third connection pattern CNP3, and the edge of the third connection pattern CNP3 may have a same (or similar) planar profile. For example, the second electrode E2b of the second light emitting element LEDb and the third connection pattern CNP3 may be in contact with each other at a position that does not overlap the second light emitting area EAb in a plan view. As a result, the second electrode E2b of the second light emitting element LEDb may be electrically connected to the second pixel driving circuit PCb through the second connection electrode CEb and the third connection pattern CNP3 without reducing a light emitting area of the second light emitting area EAb.

In an embodiment, the third connection electrode CEc may overlap the third pixel driving circuit PCc in a plan view. The third connection electrode CEc may include a third circuit connection portion CPc and a third light emitting connection portion CNc. The third circuit connection portion CPc may be a portion of the third connection electrode CEc that is electrically connected to the third pixel driving circuit PCc, and the third light emitting connection portion CNc may be a portion of the third connection electrode CEc that is electrically connected to the first connection pattern CNP1.

The first connection pattern CNP1 may be electrically connected to the third connection electrode CEc. For example, the first connection pattern CNP1 may contact (or may be electrically connected to) the third light emitting connection portion CNc of the third connection electrode CEc. The first connection pattern CNP1 may include a first sub-pattern CNP1_1, a second sub-pattern CNP1_2, and a third sub-pattern CNP1_3 electrically connected to each other. For example, the third sub-pattern CNP1_3 may extend from the first sub-pattern CNP1_1 to the second sub-pattern CNP1_2. In an embodiment, the first connection pattern CNP1 may be electrically connected to the third connection electrode CEc through at least one of the first, second, and third sub-patterns CNP1_1, CNP1_2, and CNP1_3. For example, the first sub-pattern CNP1_1 may contact the third light emitting connection portion CNc, and the second and third sub-patterns CNP1_2 and CNP1_3 may be electrically connected to the third connection electrode CEc through the first sub-pattern CNP1_1.

In an embodiment, in a plan view, the first connection pattern CNP1 may not overlap the third light emitting area EAc, and may be adjacent to (e.g., surround) at least a portion of the third light emitting area EAc. For example, the first sub-pattern CNP1_1 may be a portion of the first connection pattern CNP1 that is adjacent to (e.g., surrounds) at least a portion of the first sub-area EAc_1 in a plan view, the second sub-pattern CNP1_2 may be a portion of the first connection pattern CNP1 that is adjacent to (e.g., surrounds) at least a portion of the second sub-area EAc_2 in a plan view, and the third sub-pattern CNP1_3 may be a portion of the first connection pattern CNP1 that electrically connects the first sub-pattern CNP1_1 and the second sub-pattern CNP1_2.

The second electrode E2c of the third light emitting element LEDc may be electrically connected to the first connection pattern CNP1. For example, the second electrode E2c of the third light emitting element LEDc may contact the first connection pattern CNP1, and may be electrically connected to the third connection electrode CEc through the first connection pattern CNP1. The second electrodes E2c_1 and E2c_2 of the first and second sub-elements LEDc_1 and LEDc_2 may be electrically connected to the first and second sub-patterns CNP1_1 and CNP1_2, respectively. For example, the second electrodes E2c_1 and E2c_2 of the first and second sub-elements LEDc_1 and LEDc_2 may contact the first and second sub-patterns CNP1_1 and CNP1_2, respectively, and may be electrically connected to the third connection electrode CEc through the first connection pattern CNP1.

In an embodiment, a planar profile of an area in which the second electrodes E2c of the third light emitting element LEDc contacts the first connection pattern CNP1 (i.e., an area in which the second electrodes E2c_1 and E2c_2 of the first and second sub-elements LEDc_1 and LEDc_2 contact the first and second sub-patterns CNP1_1 and CNP1_2) may be substantially the same as or similar to a planar profile of edges of the first and second sub-patterns CNP1_1 and CNP1_2 of the first connection pattern CNP1. For example, at least a portion of the second electrodes E2c of the third light emitting element LEDc, which contacts the first connection pattern CNP1 (i.e., an area in which the second electrodes E2c_1 and E2c_2 of the first and second sub-elements LEDc_1 and LEDc_2 contact the first and second sub-patterns CNP1_1 and CNP1_2), and the edges of the first and second sub-patterns CNP1_1 and CNP1_2 of the first connection pattern CNP1 may have a same (or similar) planar profile. For example, the second electrode E2c of the third light emitting element LEDc and the first connection pattern CNP1 may be in contact with each other at a position that does not overlap the third light emitting area EAc in a plan view. For example, the second electrodes E2c_1 and E2c_2 of the first and second sub-elements LEDc_1 and LEDc_2 and the first and second sub-patterns CNP1_1 and CNP1_2 may be in contact with each other at a position that does not overlap the first and second sub-areas EAc_1 and EAc_2, respectively.

As a result, the second electrode E2c of the third light emitting element LEDc (i.e., the second electrodes E2c_1 and E2c_2 of the first and second sub-elements LEDc_1 and LEDc_2) may be electrically connected to the third pixel driving circuit PCc through the third connection electrode CEc and the first connection pattern CNP1 without reducing a light emitting area of the third light emitting area EAc.

In an embodiment, the first, second, and third connection electrodes CEa, CEb, and CEc may be spaced apart from each other, and may be separate electrodes that are distinguished from each other. For example, the first, second, and third connection electrodes CEa, CEb, and CEc may be electrically insulated from each other. According to embodiments, the shapes of the first and second unit light emitting areas UEA1 and UEA2 may be designed such that the first, second, and third connection electrodes CEa, CEb, and CEc are efficiently disposed. For example, the first and second unit light emitting areas UEA1 and UEA2 may have an optimized shape, and the first, second, and third connection electrodes CEa, CEb, and CEc may have an efficient arrangements. For example, even when the arrangement of the pixel driving circuits may not be changed (e.g., when the arrangement in which the first, second, and third pixel driving circuits PCa, PCb, and PCc along the first direction DR1 cannot be changed), the shapes of the first and second unit light emitting areas UEA1 and UEA2 may be designed such that lengths (or areas) of the first, second, and third connection electrodes CEa, CEb, and CEc may be minimized. For example, the first and second unit light emitting areas UEA1 and UEA2 may have optimized shapes without change of the arrangement of the first, second, and third pixel driving circuits PCa, PCb, and PCc, and the lengths (or the areas) of the first, second, and third connection electrodes CEa, CEb, and CEc may be decreased.

In an embodiment, the first, second, and third connection patterns CNP1, CNP2, and CNP3 may be spaced apart from each other, and may be separate patterns that are distinguished from each other. For example, the first, second, and third connection patterns CNP1, CNP2, and CNP3 may be electrically insulated from each other. In an embodiment, the first, second, and third connection patterns CNP1, CNP2, and CNP3 may include a transparent conductive oxide. However, embodiments are not limited thereto, and in an embodiment, the first, second, and third connection patterns CNP1, CNP2, and CNP3 may include a conductive material such as a metal, an alloy, a conductive metal nitride, or the like. These may be used alone or in combination with each other.

The separator SPR may overlap the first, second, and third connection patterns CNP1, CNP2, and CNP3 in a plan view, and may cover portions of the first, second, and third connection patterns CNP1, CNP2, and CNP3 and portions (e.g., portions of the pixel defining layer PDL) between adjacent connection patterns. An area in which the second electrode layer E2 contacts the first, second, and third connection patterns CNP1, CNP2, and CNP3 may be adjacent to or overlap an area in which the separator SPR is disposed in a plan view. The separator SPR may overlap the first, second, and third light emitting connection portions CNa, CNb, and CNc of the first, second, and third connection patterns CNP1, CNP2, and CNP3 in a plan view. For example, the first, second, and third connection patterns CNP1, CNP2, and CNP3 may be disposed below the separator SPR, and may not overlap the first, second, and third light emitting areas EAa, EAb, and EAc in a plan view, respectively.

The separator SPR may define first, second, third, and fourth open areas OA1, OA2, OA3, and OA4 corresponding to the second electrodes E2a, E2b, E2c_1, and E2c_2. For example, the second electrodes E2a, E2b, E2c_1, and E2c_2 may be disposed in the first, second, third, and fourth open areas OA1, OA2, OA3, and OA4, respectively. For example, the second electrode E2a of the first light emitting element LEDa may be disposed in the third open area OA3, the second electrode E2b of the second light emitting element LEDb may be disposed in the fourth open area OA4, the second electrode E2c_1 of the first sub-element LEDc of the third light emitting element LEDc may be disposed in the first open area OA1, and the second electrode E2c_2 of the second sub-element LEDc_2 of the third light emitting element LEDc may be disposed in the second open area OA2. In an embodiment, a planar shape of the first, second, third, and fourth open areas OA1, OA2, OA3, and OA4 of the separator SPR may be substantially the same as a planar shape of the second electrodes E2a, E2b, E2c_1, and E2c_2. For example, the first, second, third, and fourth open areas OA1, OA2, OA3, and OA4 of the separator SPR and the second electrodes E2a, E2b, E2c_1, and E2c_2 may have a same planar shape.

In an embodiment, the first, second, third, and fourth open areas OA1, OA2, OA3, and OA4 of the separator SPR may correspond to the first, second, and third connection patterns CNP1, CNP2, and CNP3. For example, the first and second sub-patterns CNP1_1 and CNP1_2 and the second and third connection patterns CNP2 and CNP3 may overlap the first, second, third, and fourth open areas OA1, OA2, OA3, and OA4 in a plan view, respectively. For example, the first and second sub-patterns CNP1_1 and CNP1_2 of the first connection pattern CNP1, the second connection pattern CNP2, and the third connection pattern CNP3 may be disposed in the first, second, third, and fourth open areas OA1, OA2, OA3, and OA4, respectively.

According to embodiments, the display device 21 may include a first unit light emitting area UEA1 and a second unit light emitting area UEA2 partially overlapping the corresponding unit circuit area UCA in a plan view. The shape of each of the first and second unit light emitting areas UEA1 and UEA2 may be formed such that an area occupied by the first, second, and third connection electrodes CEa, CEb, and CEc electrically connecting the second electrode layer E2 to the first, second, and third pixel driving circuits PCa, PCb, and PCc, respectively, may be reduced. Accordingly, parasitic capacitance by the first, second, and third connection electrodes CEa, CEb, and CEc may be reduced, and display quality of the display device 21 may be improved.

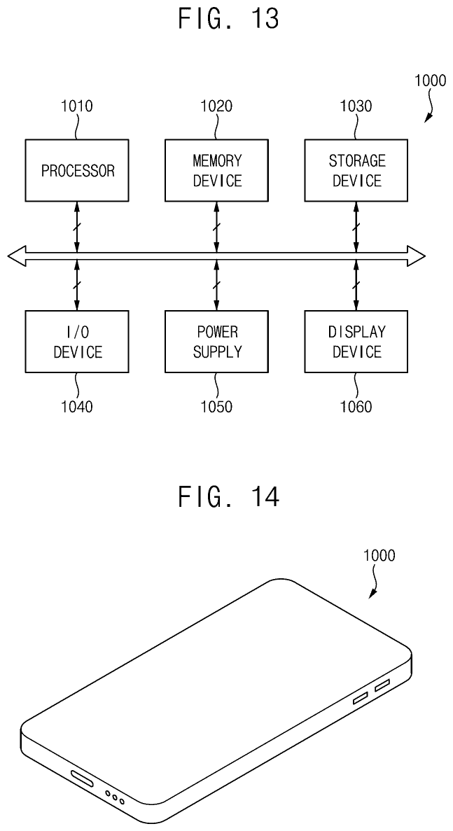

FIG. 13 is a schematic block diagram illustrating an electronic device according to an embodiment of the disclosure. FIG. 14 is a schematic view illustrating an example in which the electronic device of FIG. 13 is implemented as a smart phone.

Referring to FIGS. 13 and 14, the electronic device 1000 may include a processor 1010, a memory device 1020, a storage device 1030, an input/output (I/O) device 1040, a power supply 1050, and a display device 1060. The display device 1060 may be the display device 10 of FIG. 1A and the display device 10′ of FIG. 1B. In addition, the electronic device 1000 may further include a plurality of ports for communicating with a video card, a sound card, a memory card, a universal serial bus (USB) device, other systems, or the like.

In an embodiment, as illustrated in FIG. 14, the electronic device 1000 may be implemented as the smart phone. However, the electronic device 1000 is not limited thereto. For example, the electronic device 1000 may be implemented as a cellular phone, a video phone, a smart pad, a smart watch, a tablet PC, a car navigation system, a computer monitor, a laptop, a head mounted display (HMD) device, or the like.

The processor 1010 may perform various computing functions. The processor 1010 may be a microprocessor, a central processing unit (CPU), an application processor (AP), or the like. The processor 1010 may be coupled to other components through an address bus, a control bus, a data bus, or the like. In an embodiment, the processor 1010 may be coupled to an extended bus such as a peripheral component interconnection (PCI) bus.

The memory device 1020 may store data for operations of the electronic device 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device such as a dynamic random access memory (DRAM) device, a static random access memory (SRAM) device, a mobile DRAM device, or the like.

The storage device 1030 may include a solid-state drive (SSD) device, a hard disk drive (HDD) device, a CD-ROM device, or the like. The I/O device 1040 may include an input device such as a keyboard, a keypad, a mouse device, a touch-pad, a touch-screen, or the like, and an output device such as a printer, a speaker, or the like. In an embodiment, the I/O device 1040 may include the display device 1060.

The I/O device 1040 may include an input device such as a keyboard, a keypad, a mouse device, a touch-pad, a touch-screen, and the like, and an output device such as a printer, a speaker, and the like. In an embodiment, the I/O device 1040 may include the display device 1060.

The power supply 1050 may provide power for operations of the electronic device 1000. The display device 1060 may be connected to other components through buses or other communication links.

The disclosure can be applied to various display devices and electronic devices. For example, the disclosure is applicable to various display devices such as display devices for vehicles, ships and aircraft, portable communication devices, display devices for exhibition or information transmission, medical display devices, and the like.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first light emitting element that emits first light and includes a plurality of sub-elements spaced apart from each other;
a second light emitting element that emits second light;
a third light emitting element that emits third light;
a first pixel driving circuit electrically connected to the first light emitting element;
a second pixel driving circuit electrically connected to the second light emitting element; and
a third pixel driving circuit electrically connected to the third light emitting element,
wherein the first pixel driving circuit is disposed between the second pixel driving circuit and the third pixel driving circuit in a plan view.

2. The display device of claim 1, wherein
the plurality of sub-elements includes a first sub-element and a second sub-element,
the first sub-element overlaps the second pixel driving circuit in a plan view, and
the second sub-element overlaps the third pixel driving circuit in a plan view.

3. The display device of claim 1, wherein
the second light emitting element overlaps the second pixel driving circuit in a plan view, and
the third light emitting element overlaps the third pixel driving circuit in a plan view.

4. The display device of claim 1, wherein
the first pixel driving circuit is adjacent to the second pixel driving circuit in a first direction, and
the third pixel driving circuit is adjacent to the first pixel driving circuit in the first direction.

5. The display device of claim 4, wherein
the plurality of sub-elements includes a first sub-element and a second sub-element,
the second sub-element is spaced apart from the first sub-element in a direction between the first direction and a second direction intersecting the first direction,
the second light emitting element is spaced apart from the first sub-element in the second direction, and
the third light emitting element is spaced apart from the first sub-element in the first direction.

6. The display device of claim 1, further comprising:
a first connection electrode electrically connected to the first pixel driving circuit and overlapping the first pixel driving circuit in a plan view;
a second connection electrode electrically connected to the second pixel driving circuit and overlapping the second pixel driving circuit in a plan view; and
a third connection electrode electrically connected to the third pixel driving circuit and overlapping the third pixel driving circuit in a plan view.

7. The display device of claim 6, further comprising:
a first connection pattern electrically connected to the first connection electrode and surrounding at least a portion of the first light emitting element in a plan view;
a second connection pattern electrically connected to the second connection electrode and surrounding at least a portion of the second light emitting element in a plan view; and
a third connection pattern electrically connected to the third connection electrode and surrounding at least a portion of the third light emitting element in a plan view.

8. The display device of claim 7, wherein
the plurality of sub-elements includes a first sub-element and a second sub-element, and
the first connection pattern includes:
a first sub-pattern surrounding at least a portion of the first sub-element in a plan view;
a second sub-pattern surrounding at least a portion of the second sub-element in a plan view; and
a third sub-pattern electrically connecting the first sub-pattern and the second sub-pattern.

9. The display device of claim 8, wherein
the first sub-element includes a first sub-electrode electrically connected to the first sub-pattern,
the second sub-element includes a second sub-electrode electrically connected to the second sub-pattern,
the second light emitting element includes a first electrode electrically connected to the second connection pattern, and
the third light emitting element includes a second electrode electrically connected to the third connection pattern.

10. The display device of claim 9, further comprising:
a separator disposed on the first connection pattern, the second connection pattern, and the third connection pattern, and separating the first sub-electrode, the second sub-electrode, the first electrode, and the second electrode from each other.

11. A display device comprising:
a circuit area including:
a first pixel driving circuit;
a second pixel driving circuit adjacent to the first pixel driving circuit in a first direction; and
a third pixel driving circuit adjacent to the second pixel driving circuit in the first direction; and
a light emitting area partially overlapping the circuit area in a plan view and including:
a first light emitting area in which a first light emitting element that emits first light, electrically connected to the first pixel driving circuit, and includes a plurality of sub-elements spaced apart from each other is disposed;
a second light emitting area in which a second light emitting element that emits second light and electrically connected to the second pixel driving circuit is disposed; and
a third light emitting area in which a third light emitting element that emits third light and electrically connected to the third pixel driving circuit is disposed.

12. The display device of claim 11, wherein
the plurality of sub-elements includes a first sub-element and a second sub-element, and
the first sub-element overlaps the second pixel driving circuit in a plan view.

13. The display device of claim 11, wherein
the second light emitting element overlaps the second pixel driving circuit in a plan view, and
the third light emitting element overlaps the third pixel driving circuit in a plan view.

14. The display device of claim 11, wherein the light emitting area is defined as a rectangular planar shape having chamfered corners facing in a direction between the first direction and a second direction intersecting the first direction.

15. The display device of claim 14, wherein
the plurality of sub-elements includes a first sub-element and a second sub-element,
the second sub-element is spaced apart from the first sub-element in a direction between a direction opposite to the first direction and the second direction,
the second light emitting element is spaced apart from the first sub-element in the second direction, and
the third light emitting element is spaced apart from the first sub-element in the first direction.

16. The display device of claim 11, further comprising:
a first connection electrode electrically connected to the first pixel driving circuit and overlapping the first pixel driving circuit in a plan view;
a second connection electrode electrically connected to the second pixel driving circuit and overlapping the second pixel driving circuit in a plan view; and
a third connection electrode electrically connected to the third pixel driving circuit and overlapping the third pixel driving circuit in a plan view.

17. The display device of claim 16, further comprising:
a first connection pattern electrically connected to the first connection electrode and surrounding at least a portion of the first light emitting element in a plan view;
a second connection pattern electrically connected to the second connection electrode and surrounding at least a portion of the second light emitting element in a plan view; and
a third connection pattern electrically connected to the third connection electrode and surrounding at least a portion of the third light emitting element in a plan view.

18. The display device of claim 17, wherein
the plurality of sub-elements includes a first sub-element and a second sub-element, and
the first connection pattern includes:
a first sub-pattern surrounding at least a portion of the first sub-element in a plan view;
a second sub-pattern surrounding at least a portion of the second sub-element in a plan view; and
a third sub-pattern electrically connecting the first sub-pattern and the second sub-pattern.

19. The display device of claim 18, wherein
the first sub-element includes a first sub-electrode electrically connected to the first sub-pattern,
the second sub-element includes a second sub-electrode electrically connected to the second sub-pattern,
the second light emitting element includes a first electrode electrically connected to the second connection pattern, and
the third light emitting element includes a second electrode electrically connected to the third connection pattern.

20. The display device of claim 19, further comprising:
a separator disposed on the first connection pattern, the second connection pattern, and the third connection pattern, and separating the first sub-electrode, the second sub-electrode, the first electrode, and the second electrode from each other.

21. An electronic device comprising:
a display device; and
a power supply that provides power to the display device,
wherein the display device includes:
a first light emitting element that emits first light and includes a plurality of sub-elements spaced apart from each other;
a second light emitting element that emits second light;
a third light emitting element that emits third light;
a first pixel driving circuit electrically connected to the first light emitting element;
a second pixel driving circuit electrically connected to the second light emitting element; and
a third pixel driving circuit electrically connected to the third light emitting element,
the first pixel driving circuit is disposed between the second pixel driving circuit and the third pixel driving circuit in a plan view.
